(19) United States
(12) Patent Application Publication
(10) Pub. No.: US 2020/0028054 A1
(43) Pub. Date: Jan. 23, 2020

(54) THERMOELECTRIC CONVERSION DEVICE

(71) Applicant: TDK CORPORATION, Tokyo (JP)

(72) Inventors: Takashi ASATANI, Tokyo (JP); Makoto SHIBATA, Tokyo (JP)

(73) Assignee: TDK CORPORATION, Tokyo (JP)

(21) Appl. No.: 16/271,167

(22) Filed: Feb. 8, 2019

(30) Foreign Application Priority Data
Feb. 13, 2018 (JP) 2018-023531
Feb. 13, 2018 (JP) 2018-023532

(51) Int. Cl. H01L 35/30; H01L 35/32; H01L 35/10; H01L 27/16

(52) U.S. Cl. CPC H01L 35/30; H01L 27/16; H01L 35/10; H01L 35/32

(57) ABSTRACT

A thermoelectric conversion device includes: a substrate having a first surface and a second surface that face each other in a thickness direction; at least one thermoelectric conversion element which is provided in a surface on a side of at least one of the first surface and the second surface; a heat transfer member disposed on the side of the substrate, on which the at least one thermoelectric conversion element is provided, with an interval from at least a part of the at least one thermoelectric conversion element; and at least one heat transfer portion configured to thermally connect the at least one thermoelectric conversion element and the heat transfer member, wherein an interspace between the substrate and the heat transfer member is sealed outside a perimeter of the at least one thermoelectric conversion element.

### BACKGROUND

The present disclosure relates to a thermoelectric conversion device.

Priority is claimed on Japanese Patent Application No. 2018-023531 filed on Feb. 13, 2018, and Japanese Patent Application No. 2018-023532 filed on Feb. 13, 2018, the contents of which are incorporated herein by reference.

In view of energy saving, attention has recently been given to use of heat that disappears without being used. Particularly, in fields related to internal combustion engines or burners, research on thermoelectric conversion using exhaust heat has been conducted.

For example, PCT International Patent Publication No. WO2010/084718 proposes a packaged thermoelectric conversion module (a thermoelectric conversion device) in which the inside of an airtight container housing a thermoelectric conversion module is decompressed or evacuated. In the package thermoelectric conversion module, the inside of the airtight container is partitioned into two chambers with a partition plate. One of the chambers includes the thermoelectric conversion module and electrodes led out to the outside of the airtight container, while a flow passage for introducing a heating medium from an external heating medium supply source and circulating the heating medium between the other chamber and the external heating medium supply source is formed in the other chamber. Heat is exchanged with one surfaces of thermoelectric semiconductors by the heating medium via the partition plate, while heat is exchanged between the other surfaces of the thermoelectric semiconductors and an external heat source via the airtight container.

### SUMMARY

Meanwhile, to improve a thermoelectric conversion characteristic in the aforementioned thermoelectric conversion device, it is important to increase a difference in temperature between a hot junction side and a cold junction side of each thermoelectric conversion element. To efficiently use heat from a heat source, there is a need to concentrate the heat conducted from the heat source on the hot junction sides of the thermoelectric conversion elements.

On the other hand, in the packaged thermoelectric conversion module disclosed in Patent Document 1, there is a need to house the thermoelectric conversion module in the airtight container, the inside of which is decompressed or evacuated, to partition the inside of the airtight container into the two chambers with the partition plate, to lead the electrodes connected to the thermoelectric conversion module to the outside of the airtight container from the one chamber, and to introduce the heating medium from the external heating medium supply source into the other chamber. For this reason, there is a problem that, to secure airtightness between the two chambers, a sealing structure is complicated.

It is desirable to provide a thermoelectric conversion device capable of simplifying a sealing structure.

The present disclosure provides the following means.

[1] A thermoelectric conversion device including:

a substrate having a first surface and a second surface that face each other in a thickness direction;

at least one thermoelectric conversion element which is provided in a surface on a side of at least one of the first surface and the second surface;

a heat transfer member disposed on the side of the substrate, on which the at least one thermoelectric conversion element is provided, with an interval from at least a part of the at least one thermoelectric conversion element; and

at least one heat transfer portion configured to thermally connect the at least one thermoelectric conversion element and the heat transfer member, wherein an interspace between the substrate and the heat transfer member is sealed outside a perimeter of the at least one thermoelectric conversion element.

[2] A thermoelectric conversion device including:

at least one thermoelectric conversion element which is provided on a specific plane;

a first heat transfer member disposed on one side of the specific plane with an interval from at least a part of the at least one thermoelectric conversion element, interposing the at least one thermoelectric conversion element between the one side of the specific plane and other side of the specific plane;

a first heat transfer portion configured to thermally connect the at least one thermoelectric conversion element and the first heat transfer member;

a second heat transfer member disposed on the other side of the specific plane with an interval from at least a part of the at least one thermoelectric conversion element, interposing the at least one thermoelectric conversion element between the one side of the specific plane and the other side of the specific plane; and

a second heat transfer portion configured to thermally connect the at least one thermoelectric conversion element and the second heat transfer member,

wherein an interspace between the first heat transfer member and the second heat transfer member is sealed outside a perimeter of the at least one thermoelectric conversion element.

### BRIEF DESCRIPTION OF THE DRAWINGS

FIG. 1 is a perspective view illustrating an appearance of a thermoelectric conversion device according to a first embodiment of the present disclosure.

FIG. 2 is a perspective top view illustrating a schematic constitution of the thermoelectric conversion device illustrated in FIG. 1.

FIG. 3 is a sectional perspective view of the thermoelectric conversion device taken along line X-X′ illustrated in FIG. 2.

FIG. 4 is a sectional perspective view illustrating a schematic constitution of a thermoelectric conversion device according to a second embodiment of the present disclosure.

FIG. 5 is a sectional perspective view illustrating a schematic constitution of a thermoelectric conversion device according to a third embodiment of the present disclosure.

FIG. 6 is a sectional perspective view illustrating a schematic constitution of a thermoelectric conversion device according to a fourth embodiment of the present disclosure.

FIG. 7 is a perspective top view illustrating a schematic constitution of a thermoelectric conversion device according to a fifth embodiment of the present disclosure.

FIG. 8 is a sectional perspective view of the thermoelectric conversion device taken along line A-A′ illustrated in FIG. 7.

FIG. 9 is a sectional perspective view of the thermoelectric conversion device taken along line B-B′ illustrated in FIG. 7.

FIG. 10 is a sectional perspective view of the thermoelectric conversion device taken along line C-C′ illustrated in FIG. 7.

FIG. 11 is a sectional perspective view illustrating an outline of a thermoelectric conversion device according to a sixth embodiment of the present disclosure.

FIG. 12 is a perspective top view illustrating a schematic constitution of the thermoelectric conversion device illustrated in FIG. 11.

FIG. 13 is a sectional perspective view of the thermoelectric conversion device taken along line X-X′ illustrated in FIG. 12.

FIG. 14 is a sectional perspective view illustrating a schematic constitution of a thermoelectric conversion device according to a seventh embodiment of the present disclosure.

FIG. 15 is a sectional perspective view illustrating a schematic constitution of a thermoelectric conversion device according to an eighth embodiment of the present disclosure.

FIG. 16 is a sectional perspective view illustrating a schematic constitution of a thermoelectric conversion device according to a ninth embodiment of the present disclosure.

FIG. 17 is a sectional perspective view illustrating a schematic constitution of a thermoelectric conversion device according to a tenth embodiment of the present disclosure.

### DETAILED DESCRIPTION

Hereinafter, embodiments of the present disclosure will be described in detail with reference to the drawings.

To facilitate understanding of features, the drawings used for the following description illustrate characteristic portions in an enlarged manner in some cases for convenience, and a dimensional ratio or the like between constituent elements is not necessarily the same as in reality. Further, materials or the like exemplified in the following description are one example, and the present disclosure is not necessarily limited thereto, and can be implemented with appropriate modification without departing from the spirit and scope thereof.

### First Embodiment

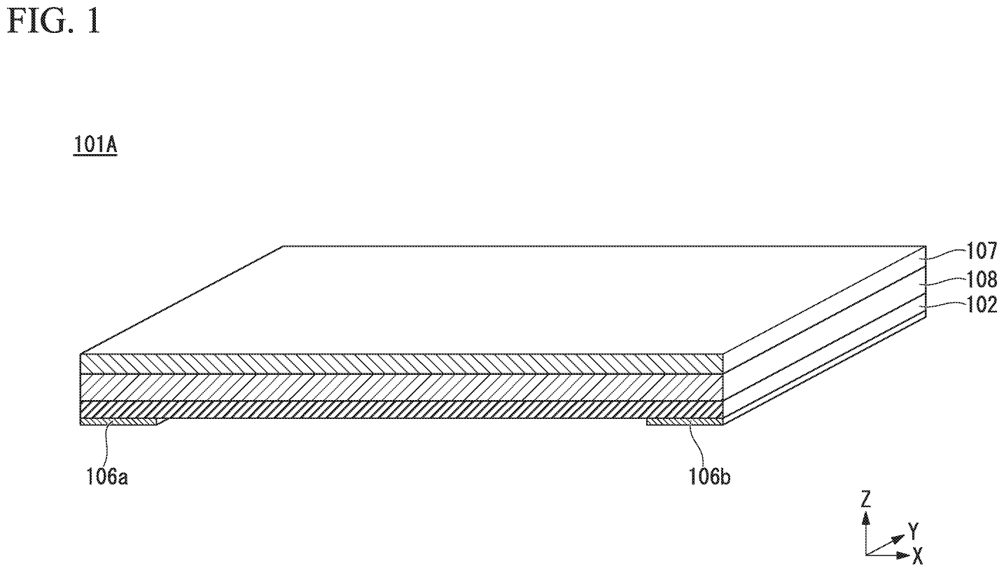

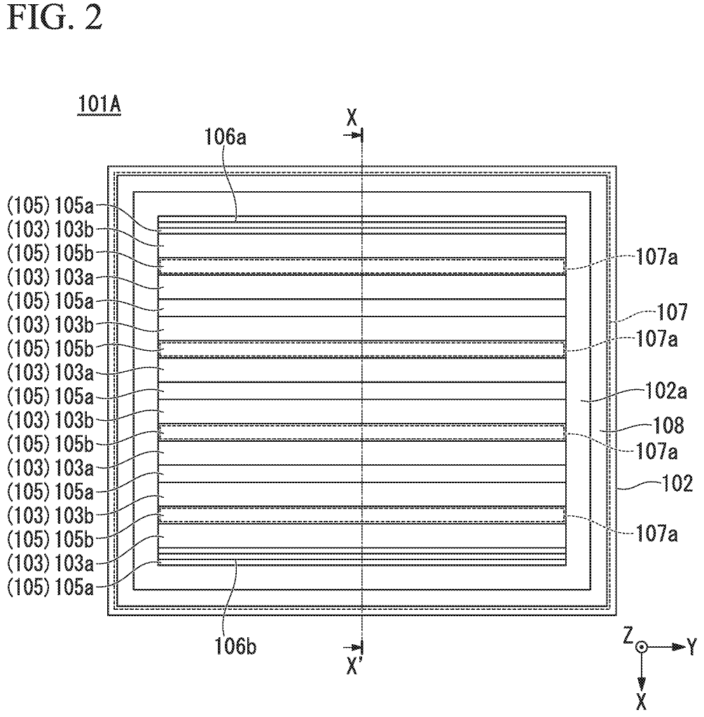

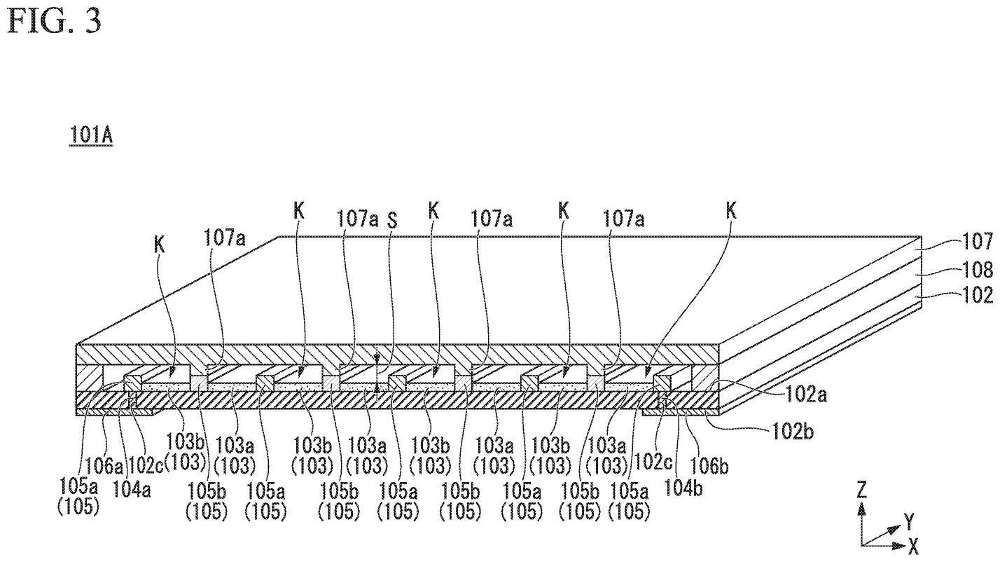

First, as a first embodiment of the present disclosure, for example, a thermoelectric conversion device 101A illustrated in FIGS. 1 to 3 will be described. FIG. 1 is a perspective view illustrating an appearance of the thermoelectric conversion device 101A. FIG. 2 is a perspective top view illustrating a schematic constitution of the thermoelectric conversion device 101A illustrated in FIG. 1. FIG. 3 is a sectional perspective view of the thermoelectric conversion device 101A taken along line X-X′ illustrated in FIG. 2.

In the drawings illustrated below, an XYZ orthogonal coordinate system is set, and indicates an X-axial direction as a first direction in a specific surface of the thermoelectric conversion device 101A, a Y-axial direction as a second direction in the specific surface of the thermoelectric conversion device 101A, and a Z-axial direction as a thickness direction (a height direction) perpendicular to the specific surface of the thermoelectric conversion device 101A.

As illustrated in FIGS. 1 to 3, the thermoelectric conversion device 101A of the present embodiment has a structure in which a plurality of thermoelectric conversion elements 103 (eight thermoelectric conversion elements in the present embodiment) disposed in a row on a surface of a substrate 102 are connected in series between a pair of through electrodes 104a and 104b.

The substrate 102 is formed of an insulating base material having a first surface 102a (an upper surface in the present embodiment) and a second surface 102b (a lower surface in the present embodiment) that face each other in the thickness direction. For example, a high-resistance silicon (Si) substrate in which sheet resistance becomes 10Ω or higher is preferably used as the substrate 102. When the sheet resistance of the substrate 102 becomes 10Ω or higher, an electric short circuit between the plurality of thermoelectric conversion elements 103 can be prevented from occurring.

For example, a silicon on insulator (SOI) substrate having an oxide insulating layer therein, a ceramic substrate, a glass substrate, another high-resistance single crystal substrate, or the like can be used as the substrate 102 in addition to the aforementioned high-resistance Si substrate. Furthermore, even if the substrate 102 is a low-resistance substrate in which sheet resistance becomes 10Ω or lower, a substrate in which a high-resistance material is disposed between the low-resistance substrate and the thermoelectric conversion elements 103 can be used as the substrate 102.

Of first and second directions that intersect each other (are orthogonal to each other in the present embodiment) in a surface (a specific surface) located on the first surface 102a of the substrate 102, the first direction is set to a transverse direction, and the second direction is set to a longitudinal direction. The plurality of thermoelectric conversion elements 103 are disposed in a row at fixed intervals in the first direction. The thermoelectric conversion elements 103 are all formed in the same size in rectangular shapes (oblong shapes in the present embodiment) in the top view.

The plurality of thermoelectric conversion elements 103 have a constitution in which first thermoelectric conversion elements (one thermoelectric conversion elements) 103a formed of any one of p-type and n-type semiconductors (an n-type semiconductor in the present embodiment) and second thermoelectric conversion elements (other thermoelectric conversion elements) 103b formed of the other of the p-type and n-type semiconductors (the p-type semiconductor in the present embodiment) are alternately disposed in a row.

In the first thermoelectric conversion elements 103a, a multilayer film of an n-type silicon (Si) film and an n-type silicon germanium (SiGe) alloy film in which, for example, antimony (Sb) of a high concentration (10¹⁸ to 10¹⁹ cm⁻³) is doped can be used. In the first thermoelectric conversion elements 103a formed of an n-type semiconductor, an electric current flows from a cold junction side toward a hot junction side.

In the second thermoelectric conversion elements 103b, a multilayer film of a p-type silicon (Si) film and a p-type silicon germanium (SiGe) alloy film in which, for example, boron (B) of a high concentration (10¹⁸ to 10¹⁹ cm⁻³) is doped can be used. In the second thermoelectric conversion elements 103b formed of a p-type semiconductor, an electric current flows from a hot junction side toward a cold junction side.

The thermoelectric conversion elements 103 are not necessarily limited to those formed of the aforementioned multilayer film of the p-type or n-type semiconductor, and may be formed of a single layer film of the p-type or n-type semiconductor. An oxide-based semiconductor can be used as the semiconductor. A thermoelectric conversion film formed of an organic polymer film or a metal film may be used. Furthermore, the thermoelectric conversion elements 103 are not limited to the aforementioned thermoelectric conversion film, and a film formed of a bulk may be used.

The thermoelectric conversion device 101A of the present embodiment includes a plurality of electrodes 105 (nine electrodes in the present embodiment) that are provided in a row in an array direction (the first direction) of the plurality of thermoelectric conversion elements 103. The plurality of thermoelectric conversion elements 103 are disposed between first electrodes 105a and second electrodes 105b that are alternately adjacent to each other in the array direction of the plurality of electrodes 105, and are electrically connected to the first electrodes 105a and the second electrodes 105b.

The plurality of electrodes 105 are all formed in the same size in rectangular shapes (oblong shapes in the present embodiment) in the top view over the entire region in the longitudinal direction (the second direction) of the thermoelectric conversion elements 103 in a state in which they are in contact with lateral surfaces of one end sides and the other end sides of the thermoelectric conversion elements 103 which face each other in the first direction. For example, copper (Cu) or gold (Au) that have high electrical conductivity and thermal conductivity and for which shape machining is easy can be appropriately used for the electrodes 105.

The plurality of electrodes 105 have a constitution in which the five first electrodes 105a serving as cold junction side electrodes and the four second electrodes 105b serving as hot junction side electrodes are alternately disposed in a row. The first electrodes 105a are arranged on one end side (a +X side in the present embodiment) of each of the first thermoelectric conversion elements 103a and one end side (a −X side in the present embodiment) of each of the second thermoelectric conversion elements 103b. On the other hand, the second electrodes 105b are arranged on the other end side (the −X side in the present embodiment) of each of the first thermoelectric conversion elements 103a and the other end side (the +X side in the present embodiment) of each of the second thermoelectric conversion elements 103b. That is, in the thermoelectric conversion device 101A of the present embodiment, the one end side of each of the first thermoelectric conversion elements 103a becomes the +X side, and the other end side of each of the first thermoelectric conversion elements 103a becomes the −X side. On the other hand, the one end side of each of the second thermoelectric conversion elements 103b becomes the −X side, and the other end side of each of the second thermoelectric conversion elements 103b becomes the +X side.

In the first thermoelectric conversion elements 103a formed of the n-type semiconductor, an electric current flows from the side of the first electrodes 105a acting as cold junctions toward the side of the second electrodes 105b acting as hot junctions. On the other hand, in the second thermoelectric conversion elements 103b formed of the p-type semiconductor, an electric current flows from the side of the second electrodes 105b acting as hot junctions toward the side of the first electrodes 105a acting as cold junctions.

Therefore, in the thermoelectric conversion device 101A of the present embodiment, a direction of the electric current flowing to the first thermoelectric conversion elements 103a and a direction of the electric current flowing to the second thermoelectric conversion elements 103b are the same.

The pair of through electrodes 104a and 104b are provided in a state in which they pass through the substrate 102 in the thickness direction. The pair of through electrodes 104a and 104b are both formed in the same size in rectangular shapes (oblong shapes in the present embodiment) in the top view to be connected over the entire region in the longitudinal direction (the second direction) of the first electrodes 105a at middle portions of the first electrodes 105a located at opposite ends in the array direction (the first direction) of the thermoelectric conversion elements 103.

Further, the pair of through electrodes 104a and 104b are provided in a state in which they are embedded in holes 2c passing through the substrate 102 in the thickness direction by through-hole plating or the like. For example, copper (Cu) or gold (Au) can be appropriately used for the pair of through electrodes 104a and 104b as a conductive material that can be embedded in these holes 2c. The pair of through electrodes 104a and 104b are not limited to a state in which they are embedded in the hole parts 2c in a solid state, and can also be embedded in circumferences of the holes 2c in a hollow state.

Thereby, one 104a of the pair of through electrodes 104a and 104b is electrically connected to the first electrode 105a that is disposed on the −X sides of the thermoelectric conversion elements 103 (the second thermoelectric conversion elements 103b in the present embodiment) located on one endmost side (the −X side) in the array direction (the first direction) of the thermoelectric conversion elements 103. In contrast, the other through electrode 104b is electrically connected to the first electrode 105a that is disposed on the +X sides of the thermoelectric conversion elements 103 (the first thermoelectric conversion elements 103a in the present embodiment) located on the other endmost side (the +X side) in the array direction (the first direction) of the thermoelectric conversion elements 103.

Furthermore, the pair of through electrodes 104a and 104b are electrically connected to a pair of terminals 106a and 106b provided on the second surface 102b of the substrate 102. The pair of terminals 106a and 106b are both formed in the same size in rectangular shapes (oblong shapes in the present embodiment) in the top view to be located at opposite ends of the second surface 102b in the first direction and connected to the pair of through electrodes 104a and 104b over the entire region in the second direction. The same thing as the electrodes 105 may be used for the pair of terminals 106a and 106b.

Thereby, one terminal 106a of the pair of terminals 106a and 106b is electrically connected to the first electrode 105a that is disposed on the −X sides of the thermoelectric conversion elements 103 (the second thermoelectric conversion elements 103b in the present embodiment) located on one endmost side (the −X side) in the array direction (the first direction) of the thermoelectric conversion elements 103 via one of the through electrodes 104a. In contrast, the other terminal 106b is electrically connected to the first electrode 105a that is disposed on the +X sides of the thermoelectric conversion elements 103 (the first thermoelectric conversion elements 103a in the present embodiment) located on the other endmost side (the +X side) in the array direction (the first direction) of the thermoelectric conversion elements 103 via the other through electrode 104b.

The thermoelectric conversion device 101A of the present embodiment includes a heat transfer plate 107 that is thermally connected to the thermoelectric conversion elements 103 via heat transfer portions 107a. In the thermoelectric conversion device 101A, the heat transfer plate 107 is disposed on a high temperature (a heat source) side, and the substrate 102 is disposed on a low temperature (heat radiation/cooling) side.

The heat transfer plate 107 acts as a heat transfer member of the high temperature (the heat source) side, and is formed of a material having higher thermal conductivity than air, and preferably a material having higher thermal conductivity than the substrate 102. A metal is preferably used as the material of this heat transfer plate 107, and among them, particularly, for example, aluminum (Al) or copper (Cu) that have high thermal conductivity and for which shape machining is easy can be appropriately used. A ceramic material such as aluminum oxide (Al₂O₃) can be used as the material of the heat transfer plate 107. The heat transfer plate 107 may be constituted of a plurality of members.

The heat transfer plate 107 faces the side of the surface (the first surface 102a in the present embodiment) on which the thermoelectric conversion elements 103 of the substrate 102 are provided, and is disposed at an interval S from the thermoelectric conversion elements 103 and the first electrodes 105a. The interval S may be partly different due to a difference in thickness between the thermoelectric conversion element and the first electrode 105a.

The heat transfer portions 107a are formed by protrusions that protrude from any one of surfaces of the heat transfer plate 107 and the second electrodes 105b which face each other. The heat transfer portions 107a of the present embodiment are formed by the protrusions that protrude from positions of the heat transfer plate 107 which face the second electrodes 105b toward a lower side that is the side of the thermoelectric conversion elements 103 (in the −Z direction). For the protrusions (the heat transfer portions 107a), the same materials exemplified for the aforementioned heat transfer plate 107 can be used. The heat transfer portions 107a can be formed integrally with the heat transfer plate 107.

The heat transfer portions 107a each have a rectangular shape (an oblong shape in the present embodiment) in the top view, and are provided to protrude in a region in which they overlap the second electrodes 105b in the top view. The protrusions by which the heat transfer portions 107a are formed are in a state in which tips thereof abut on the second electrodes 105b. Thereby, the heat transfer plate 107 is thermally connected with the other end sides of the thermoelectric conversion elements 103 (the −X sides of the first thermoelectric conversion elements 103a and the +X sides of the second thermoelectric conversion elements 103b) via the protrusions (the heat transfer portions 107a). The tips of the heat transfer portions 107a are thermally connected with the second electrodes 105b via an insulating layer (not shown) in a state in which they are electrically insulated from the second electrodes 105b. Thereby, spaces K are provided between the heat transfer portions 107a adjacent to each other.

An insulating material having higher thermal conductivity than air, such as, for example, aluminum oxide (Al₂O₃), silicon oxide (SiO₂), silicon nitride (SiN), or aluminum nitride (AlN) can be used for the insulating layer as the material of which a part of each of the heat transfer portions 107a is formed. For example, a UV curable resin, a silicone-based resin, or thermal conductive grease (for example, silicone-based grease or non-silicone-based grease containing a metal oxide) can be used. In the case where electric insulation between the tips of the heat transfer portions 107a and the second electrodes 105b does not cause any problems, the tips of the heat transfer portions 107a and the second electrodes 105b may be directly connected to each other without providing the aforementioned insulating layers.

Further, the heat transfer portions 107a are not limited to the case where they are formed by the protrusions protruding from the side of the aforementioned heat transfer plate 107, and may be formed by protrusions that protrude from the side of the second electrodes 105b toward an upper side that is the side of the heat transfer plate 107 (in the +Z direction). These protrusions can be formed, for example, by making thicknesses of the second electrodes 105b larger than those of the thermoelectric conversion elements 103, and the heat transfer plate 107 and the thermoelectric conversion elements 103 (the second electrodes 105b) can also be thermally connected with each other via these protrusions. Furthermore, other members (including the above insulating layers) that are thermally connected between the heat transfer plate 107 and the thermoelectric conversion elements 103 (the second electrodes 105b) can also be provided as the heat transfer portions 107a.

In the thermoelectric conversion device 101A of the present embodiment, the interspace between the substrate 102 and the heat transfer plate 107 is sealed outside perimeters of the plurality of thermoelectric conversion elements 103 via a sealing member 108. The sealing member 108 is formed of, for example, an adhesive resistant to high temperatures such as a silicone-based adhesive, and is sealed to surround a perimeter between the substrate 102 and the heat transfer plate 107.

The decompressed spaces K are provided between the substrate 102 and the heat transfer plate 107 sealed with the sealing member 108. That is, the decompressed spaces K are provided between the heat transfer plate 107 and each of the thermoelectric conversion elements 103 and the first electrodes 105a.

The decompressed spaces K can be formed using a method of sealing the substrate 102 and the heat transfer plate 107 with the sealing member 108 under a decompressed atmosphere, a method of providing a hole in a part of the sealing member 108 and sealing the hole after the spaces K are decompressed through the hole, or the like. The thermoelectric conversion device 101A of the present embodiment can also have a constitution in which the spaces K are filled with a low thermal conductive material (including air) having lower thermal conductivity than the heat transfer portions 107a.

In the thermoelectric conversion device 101A of the present embodiment having the constitution described above, heat conducted from a heat source (not shown) to the heat transfer plate 107 is conducted to the second electrodes 105b via the heat transfer portions 107a. Thereby, the side of the second electrodes 105b of the thermoelectric conversion elements 103 reaches a relatively higher temperature than the side of the first electrodes 105a, and a difference in temperature between the first electrodes 105a and the second electrodes 105b of the thermoelectric conversion elements 103 occurs.

Thereby, movement of charges (carriers) between the first electrodes 105a and the second electrodes 105b of the thermoelectric conversion elements 103 occurs. That is, electromotive forces (voltages) are generated between the first electrodes 105a and the second electrodes 105b of the thermoelectric conversion elements 103 due to a Seebeck effect.

Here, although the electromotive force (the voltage) generated from one of the thermoelectric conversion elements 103 is small, the first thermoelectric conversion elements 103a and the second thermoelectric conversion elements 103b are alternately connected in series between the one through electrode 104a and the other through electrode 104b. A relatively high voltage can be taken out between the one through electrode 104a and the other through electrode 104b as the sum of the electromotive forces.

In the thermoelectric conversion device 101A of the present embodiment, the heat transfer plate 107 and the thermoelectric conversion elements 103 are thermally connected with each other via the aforementioned heat transfer portions 107a. Meanwhile, the heat transfer plate 107 is disposed at the interval S from the thermoelectric conversion elements 103 and the first electrodes 105a.

In the case of this constitution, the heat conducted from the heat source to the heat transfer plate 107 is concentrically conducted to the second electrodes 105b acting as the hot junctions via the heat transfer portions 107a. On the other hand, the heat conducted from the heat source to the heat transfer plate 107 is hardly conducted to the first electrodes 105a acting as the cold junctions. Thereby, a large difference in temperature between the hot junction and the cold junction of each of the thermoelectric conversion elements 103 is obtained, and thereby high output can be obtained.

In the thermoelectric conversion device 101A of the present embodiment, the substrate 102 and the heat transfer plate 107 are sealed outside the perimeters of the aforementioned plurality of thermoelectric conversion elements 103, and a sealing structure therebetween can be simplified.

Furthermore, in the thermoelectric conversion device 101A of the present embodiment, the decompressed spaces K are provided between the aforementioned heat transfer plate 107, and the thermoelectric conversion elements 103 and the first electrodes 105a. The spaces K have a function of obstructing (insulating) conduction of the heat. Thereby, since less of the heat conducted from the heat source to the heat transfer plate 107 is conducted to the first electrodes 105a, higher output can be obtained while enlarging the difference in temperature between the hot junction and the cold junction of each of the thermoelectric conversion elements 103.

In the thermoelectric conversion device 101A of the present embodiment, the pair of terminals 106a and 106b can be electrically connected to the plurality of thermoelectric conversion elements 103 via the pair of through electrodes 104a and 104b that pass through the aforementioned substrate 102. Thereby, the sealing structure between the substrate 102 and the heat transfer plate 107 can be simplified without having an influence on a sealing portion between the substrate 102 and the heat transfer plate 107 (a portion where the sealing member 108 is provided).

As described above, in the thermoelectric conversion device 101A of the present embodiment, the thermoelectric conversion characteristic of the thermoelectric conversion device 101A can be improved while simplifying the sealing structure.

### Second Embodiment

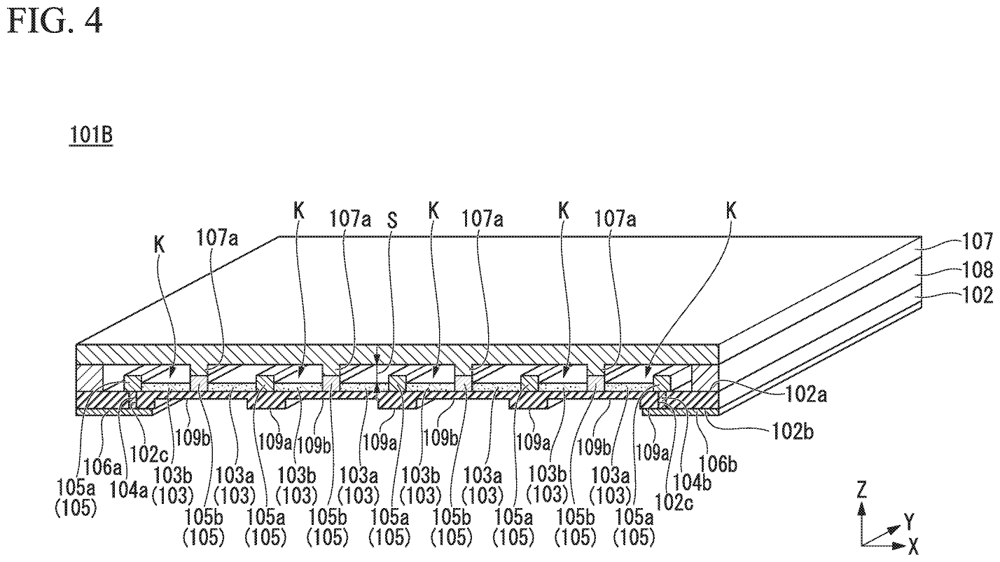

Next, a thermoelectric conversion device 101B illustrated, for example, in FIG. 4 will be described as a second embodiment of the present disclosure. FIG. 4 is a sectional perspective view illustrating a schematic constitution of the thermoelectric conversion device 101B. Further, in the following description, with respect to parts equivalent to those of the thermoelectric conversion device 101A, description will be omitted, and the same reference signs will be given in the drawing.

As illustrated in FIG. 4, the thermoelectric conversion device 101B of the present embodiment has a constitution in which the thicknesses of the portions that face the first electrodes 105a acting as at least the cold junctions in the substrate 102 which the thermoelectric conversion device 101A includes are greater than those of the portions that face the second electrodes 105b acting as at least the hot junctions.

To be specific, a plurality of protrusions 109a (five protrusions in the present embodiment) and a plurality of recesses 109b (four recesses in the present embodiment) are alternately arranged on a second surface 102b of the substrate 102 in a first direction, whereas a first surface 102a of the substrate 102 is a flat surface.

The plurality of protrusions 109a are provided to protrude at a fixed height in a region in which they overlap the first electrodes 105a in the top view. The plurality of recesses 109b are provided between the plurality of protrusions 109a to be recessed at a fixed depth. Thereby, thicknesses of portions where the protrusions 109a of the substrate 102 are provided are greater than those of portions where the recesses 109b are provided.

The protrusions 109a located at opposite ends in the first direction are provided to extend at a fixed height to opposite ends of the second surface 102b in the first direction. A pair of terminals 106a and 106b are provided on surfaces of the protrusions 109a located at the opposite ends in the first direction.

In the thermoelectric conversion device 101B of the present embodiment having the constitution described above, the heat transfer plate 107 and the thermoelectric conversion elements 103 are thermally connected with each other via the aforementioned heat transfer portions 107a. Meanwhile, the heat transfer plate 107 is disposed at an interval S from the thermoelectric conversion elements 103 and the first electrodes 105a.

In the case of this constitution, heat conducted from a heat source to the heat transfer plate 107 is concentrically conducted to the second electrodes 105b acting as the hot junctions via the heat transfer portions 107a. On the other hand, the heat conducted from the heat source to the heat transfer plate 107 is hardly conducted to the first electrodes 105a acting as the cold junctions. Thereby, a large difference in temperature between the hot junction and the cold junction of each of the thermoelectric conversion elements 103 is obtained, and thereby high output can be obtained.

In the thermoelectric conversion device 101B of the present embodiment, thicknesses of portions that face the first electrodes 105a acting as the cold junctions of the aforementioned substrate 102 (portions where the protrusions 109a are provided) are greater than those of portions that face the second electrodes 105b acting as the hot junctions (portions where the recesses 109b are provided).

In the case of this constitution, the heat conducted from the heat source to the heat transfer plate 107 is conducted to the second electrodes 105b acting as the hot junctions via the heat transfer portions 107a, is conducted to the first electrodes 105a acting as the cold junctions via the thermoelectric conversion elements 103, and is conducted from the second electrodes 105b acting as the hot junctions to the first electrodes 105a acting as the cold junctions via the substrate 102.

In this case, the thicknesses of the portions that face the first electrodes 105a of the substrate 102 (the portions where the protrusions 109a are provided) are greater than those of the portions that face the second electrodes 105b (the portions where the recesses 109b are provided), and thereby the heat can easily radiate to the outside of the substrate 102 using the portions where the protrusions 109a are provided as heat radiating parts. Thereby, a large difference in temperature between the hot junction and the cold junction of each of the thermoelectric conversion elements 103 is obtained, and thereby higher output can be obtained.

In the thermoelectric conversion device 101B of the present embodiment, the substrate 102 and the heat transfer plate 107 are sealed outside the perimeters of the aforementioned plurality of thermoelectric conversion elements 103, and a sealing structure therebetween can be simplified.

Furthermore, in the thermoelectric conversion device 101B of the present embodiment, decompressed spaces K are provided between the aforementioned heat transfer plate 107, and the thermoelectric conversion elements 103 and the first electrodes 105a. The spaces K have a function of obstructing (insulating) conduction of the heat. Thereby, since less of the heat conducted from the heat source to the heat transfer plate 107 is conducted to the first electrodes 105a, higher output can be obtained while enlarging the difference in temperature between the hot junction and the cold junction of each of the thermoelectric conversion elements 103.

In the thermoelectric conversion device 101B of the present embodiment, the pair of terminals 106a and 106b can be electrically connected to the plurality of thermoelectric conversion elements 103 via a pair of through electrodes 104a and 104b that pass through the aforementioned substrate 102. Thereby, the sealing structure between the substrate 102 and the heat transfer plate 107 can be simplified without having an influence on a sealing portion between the substrate 102 and the heat transfer plate 107 (a portion where a sealing member 108 is provided).

As described above, in the thermoelectric conversion device 101B of the present embodiment, a thermoelectric conversion characteristic of the thermoelectric conversion device 101B can be improved while simplifying the sealing structure.

### Third Embodiment

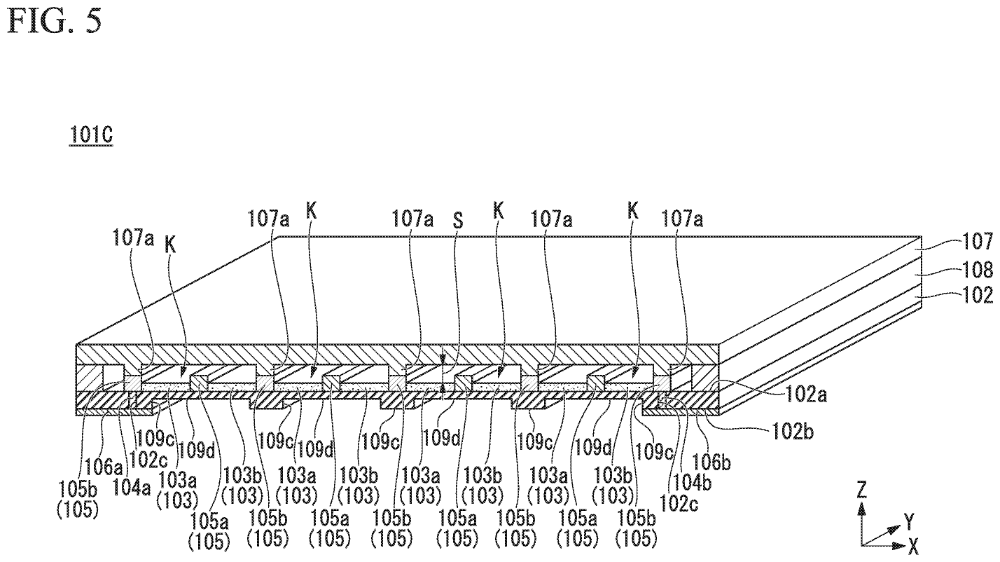

Next, a thermoelectric conversion device 101C illustrated, for example, in FIG. 5 will be described as a third embodiment of the present disclosure. FIG. 5 is a sectional perspective view illustrating a schematic constitution of the thermoelectric conversion device 101C. Further, in the following description, with respect to parts equivalent to those of the thermoelectric conversion device 101A, description will be omitted, and the same reference signs will be given in the drawing.

As illustrated in FIG. 5, the thermoelectric conversion device 101C of the present embodiment has a constitution in which the thicknesses of the portions that face the second electrodes 105b acting as at least the hot junctions in the substrate 102 which the thermoelectric conversion device 101A includes are greater than those of the portions that face the first electrodes 105a acting as at least the cold junctions.

To be specific, a plurality of protrusions 109c (five protrusions in the present embodiment) and a plurality of recesses 109d (four recesses in the present embodiment) are alternately arranged on a second surface 102b of the substrate 102 in a first direction, whereas a first surface 102a of the substrate 102 is a flat surface.

The plurality of protrusions 109c are provided to protrude at a fixed height in a region in which they overlap the second electrodes 105b in the top view. The plurality of recesses 109d are provided between the plurality of protrusions 109c to be recessed at a fixed depth. Thereby, thicknesses of portions where the protrusions 109c of the substrate 102 are provided are greater than those of portions where the recesses 109d are provided.

The protrusions 109c located at opposite ends in the first direction are provided to extend at a fixed height to opposite ends of the second surface 102b in the first direction. A pair of terminals 106a and 106b are provided on surfaces of the protrusions 109c located at the opposite ends in the first direction.

In the thermoelectric conversion device 101C of the present embodiment, arrangement of a plurality of thermoelectric conversion elements 103, which are constituted of first thermoelectric conversion elements 103a formed of an n-type semiconductor and second thermoelectric conversion elements 103b formed of a p-type semiconductor, is opposite to that of the plurality of thermoelectric conversion elements 103 which the thermoelectric conversion device 101A includes. In contrast, arrangement of a plurality of electrodes 105, which are constituted of four first electrodes 105a acting as cold junction side electrodes and five second electrodes 105b acting as hot junction side electrodes, is opposite to that of the plurality of electrodes 105 which the thermoelectric conversion device 101A includes.

In the thermoelectric conversion device 101C of the present embodiment having the constitution described above, a heat transfer plate 107 and the thermoelectric conversion elements 103 are thermally connected with each other via heat transfer portions 107a as described above. Meanwhile, the heat transfer plate 107 is disposed at an interval S from the thermoelectric conversion elements 103 and the first electrodes 105a.

In the case of this constitution, heat conducted from a heat source to the heat transfer plate 107 is concentrically conducted to the second electrodes 105b acting as the hot junctions via the heat transfer portions 107a. On the other hand, the heat conducted from the heat source to the heat transfer plate 107 is hardly conducted to the first electrodes 105a acting as the cold junctions. Thereby, a large difference in temperature between the hot junction and the cold junction of each of the thermoelectric conversion elements 103 is obtained, and thereby high output can be obtained.

In the thermoelectric conversion device 101C of the present embodiment, thicknesses of portions that face the second electrodes 105b acting as the hot junctions of the aforementioned substrate 102 (portions where the protrusions 109c are provided) are greater than those of portions that face the first electrodes 105a acting as the cold junctions (portions where the recesses 109d are provided).

In the case of this constitution, the heat conducted from the heat source to the heat transfer plate 107 is conducted to the second electrodes 105b acting as the hot junctions via the heat transfer portions 107a, is conducted to the first electrodes 105a acting as the cold junctions via the thermoelectric conversion elements 103, and is conducted from the second electrodes 105b acting as the hot junctions to the first electrodes 105a acting as the cold junctions via the substrate 102.

In this case, the thicknesses of the portions that face the first electrodes 105a of the substrate 102 (the portions where the protrusions 109c are provided) are greater than those of the portions that face the second electrodes 105b (the portions where the recesses 109d are provided), and thereby the heat can be concentrically conducted to the side of the second electrodes 105b using the portions where the protrusions 109c are provided as heat receiving parts. Thereby, a large difference in temperature between the hot junction and the cold junction of each of the thermoelectric conversion elements 103 is obtained, and thereby higher output can be obtained.

In the thermoelectric conversion device 101C of the present embodiment, the substrate 102 and the heat transfer plate 107 are sealed outside the perimeters of the aforementioned plurality of thermoelectric conversion elements 103, and a sealing structure therebetween can be simplified.

Furthermore, in the thermoelectric conversion device 101C of the present embodiment, decompressed spaces K are provided between the aforementioned heat transfer plate 107 and each of the thermoelectric conversion elements 103 and the first electrodes 105a. The spaces K have a function of obstructing (insulating) conduction of the heat. Thereby, since less of the heat conducted from the heat source to the heat transfer plate 107 is conducted to the first electrodes 105a, higher output can be obtained while enlarging the difference in temperature between the hot junction and the cold junction of each of the thermoelectric conversion elements 103.

In the thermoelectric conversion device 101C of the present embodiment, the pair of terminals 106a and 106b can be electrically connected to the plurality of thermoelectric conversion elements 103 via a pair of through electrodes 104a and 104b that pass through the aforementioned substrate 102. Thereby, the sealing structure between the substrate 102 and the heat transfer plate 107 can be simplified without having an influence on a sealing portion between the substrate 102 and the heat transfer plate 107 (a portion where a sealing member 108 is provided).

As described above, in the thermoelectric conversion device 101C of the present embodiment, a thermoelectric conversion characteristic of the thermoelectric conversion device 101C can be improved while simplifying the sealing structure.

### Fourth Embodiment

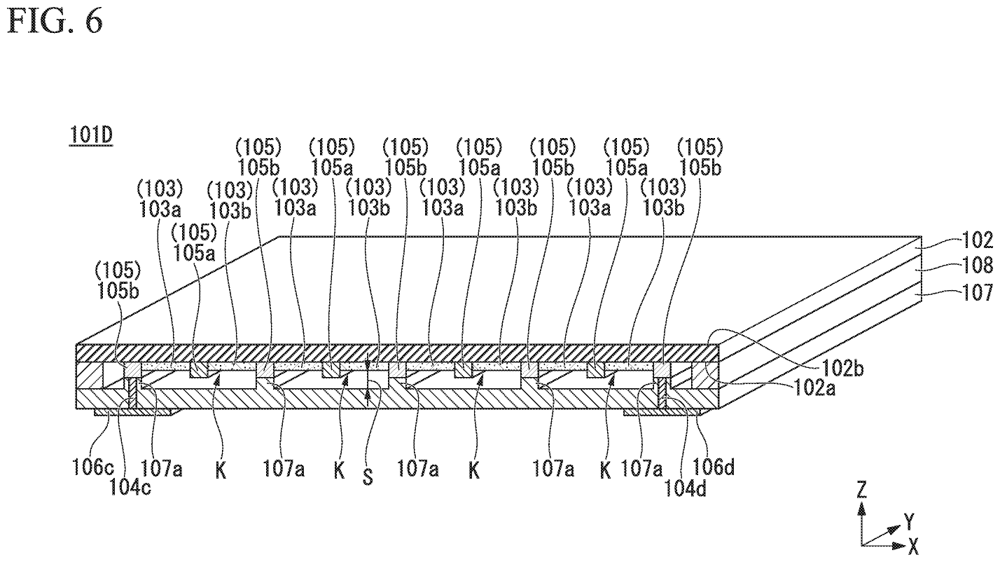

Next, a thermoelectric conversion device 101D illustrated, for example, in FIG. 6 will be described as a fourth embodiment of the present disclosure. FIG. 6 is a sectional perspective view illustrating a schematic constitution of the thermoelectric conversion device 101D. Further, in the following description, with respect to parts equivalent to those of the thermoelectric conversion device 101A, description will be omitted, and the same reference signs will be given in the drawing.

As illustrated in FIG. 6, the thermoelectric conversion device 101D of the present embodiment has a constitution in which a pair of through electrodes 104c and 104d that pass through a heat transfer plate 107 are provided instead of the pair of through electrodes 104a and 104b which the thermoelectric conversion device 101A includes. In contrast, a pair of terminals 106c and 106d that are electrically connected to the pair of through electrodes 104c and 104d are configured to be provided on a surface of the heat transfer plate 107.

In the thermoelectric conversion device 101D of the present embodiment, arrangement of a plurality of thermoelectric conversion elements 103, which are constituted of first thermoelectric conversion elements 103a formed of an n-type semiconductor and second thermoelectric conversion elements 103b formed of a p-type semiconductor, is opposite to that of the plurality of thermoelectric conversion elements 103 which the thermoelectric conversion device 101A includes. In contrast, arrangement of a plurality of electrodes 105, which are constituted of four first electrodes 105a acting as cold junction side electrodes and five second electrodes 105b acting as hot junction side electrodes, is opposite to that of the plurality of electrodes 105 which the thermoelectric conversion device 101A includes.

A plurality of the heat transfer portions 107a protrude to correspond to the second electrodes 105b in a region in which they overlap the second electrodes 105b in the top view, and are thereby in a state in which tips thereof abut on the second electrodes 105b. The tips of the heat transfer portions 107a are thermally connected with the second electrodes 105b via an insulating layer (not shown) in a state in which they are electrically insulated from the second electrodes 105b.

The pair of through electrodes 104c and 104d are connected over the entire region in a longitudinal direction (a second direction) of the second electrodes 105b at middle portions of the second electrodes 105b in a state in which they pass through the heat transfer portions 107a and the heat transfer plate 107 located at opposite ends in an array direction (a first direction) of the thermoelectric conversion elements 103. Thereby, the pair of terminals 106c and 106d are electrically connected to the second electrodes 105b, which are located at the opposite ends in the array direction (the first direction) of the thermoelectric conversion elements 103, via the pair of through electrodes 104c and 104d. Further, the pair of through electrodes 104c and 104d and the pair of terminals 106c and 106d are electrically insulated from the heat transfer portions 107a and the heat transfer plate 107.

In the thermoelectric conversion device 101D of the present embodiment having the constitution described above, the heat transfer plate 107 and the thermoelectric conversion elements 103 are thermally connected with each other via the aforementioned heat transfer portions 107a. Meanwhile, the heat transfer plate 107 is disposed at an interval S from the thermoelectric conversion elements 103 and the first electrodes 105a.

In the case of this constitution, heat conducted from a heat source to the heat transfer plate 107 is concentrically conducted to the second electrodes 105b acting as hot junctions via the heat transfer portions 107a. On the other hand, the heat conducted from the heat source to the heat transfer plate 107 is hardly conducted to the first electrodes 105a acting as cold junctions. Thereby, a large difference in temperature between the hot junction and the cold junction of each of the thermoelectric conversion elements 103 is obtained, and thereby high output can be obtained.

In the thermoelectric conversion device 101D of the present embodiment, the substrate 102 and the heat transfer plate 107 are sealed outside the perimeters of the aforementioned plurality of thermoelectric conversion elements 103, and a sealing structure therebetween can be simplified.

Furthermore, in the thermoelectric conversion device 101D of the present embodiment, decompressed spaces K are provided between the aforementioned heat transfer plate 107 and each of the thermoelectric conversion elements 103 and the first electrodes 105a. The spaces K have a function of obstructing (insulating) conduction of the heat. Thereby, since less of the heat conducted from the heat source to the heat transfer plate 107 is conducted to the first electrodes 105a, higher output can be obtained while enlarging the difference in temperature between the hot junction and the cold junction of each of the thermoelectric conversion elements 103.

In the thermoelectric conversion device 101D of the present embodiment, the pair of terminals 106c and 106d can be electrically connected to the plurality of thermoelectric conversion elements 103 via a pair of through electrodes 104c and 104d that pass through the aforementioned heat transfer plate 107. Thereby, the sealing structure between the substrate 102 and the heat transfer plate 107 can be simplified without having an influence on a sealing portion between the substrate 102 and the heat transfer plate 107 (a portion where a sealing member 108 is provided).

As described above, in the thermoelectric conversion device 101D of the present embodiment, a thermoelectric conversion characteristic of the thermoelectric conversion device 101D can be improved while simplifying the sealing structure.

### Fifth Embodiment

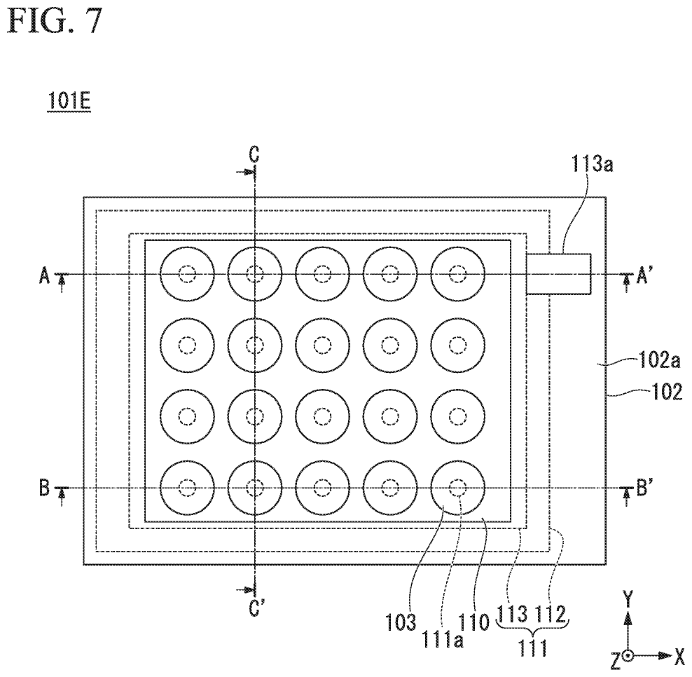

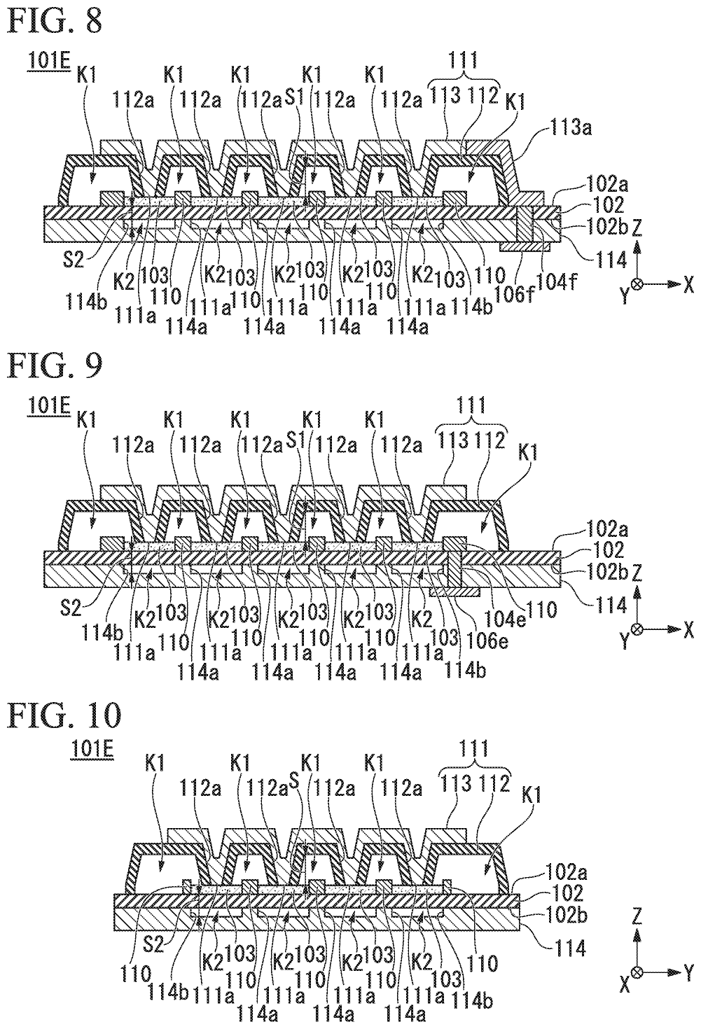

Next, a thermoelectric conversion device 101E illustrated, for example, in FIGS. 7 to 10 will be described as a fifth embodiment of the present disclosure. FIG. 7 is a perspective top view illustrating a schematic constitution of the thermoelectric conversion device 101E. FIG. 8 is a sectional view of the thermoelectric conversion device 101E taken along line A-A′ illustrated in FIG. 7. FIG. 9 is a sectional view of the thermoelectric conversion device 101E taken along line B-B′ illustrated in FIG. 7. FIG. 10 is a sectional view of the thermoelectric conversion device 101E taken along line C-C′ illustrated in FIG. 7. Further, in the following description, with respect to parts equivalent to those of the thermoelectric conversion device 101A, description will be omitted, and the same reference signs will be given in the drawing.

As illustrated in FIGS. 7 to 10, the thermoelectric conversion device 101E of the present embodiment has a constitution in which a plurality of thermoelectric conversion elements 103 (twenty thermoelectric conversion elements in the present embodiment) arranged on a surface of a substrate 102 are connected in parallel between a pair of through electrodes 104e and 104f.

The plurality of thermoelectric conversion elements 103 are provided in a row in first and second directions that intersect each other (are orthogonal to each other in the present embodiment) in a surface (a specific surface) located on a first surface 102a of the substrate 102. In the present embodiment, five thermoelectric conversion elements 103 in the first direction and four thermoelectric conversion elements 103 in the second direction are provided in a row. The thermoelectric conversion elements 103 are mutually formed in the same size in a circular shape in the top view. The plurality of thermoelectric conversion elements 103 are formed of any one of a p-type semiconductor and an n-type semiconductor. A thermoelectric conversion element equal to the first thermoelectric conversion elements 103a or the second thermoelectric conversion elements 103b can be used for the thermoelectric conversion elements 103.

The thermoelectric conversion device 101E of the present embodiment includes a lower electrode (edge electrode) 110 that electrically connects the plurality of thermoelectric conversion elements 103. The lower electrode 110 is formed to surround the perimeters of the thermoelectric conversion elements 103 in a state in which it is in contact with outer circumferential portions of the thermoelectric conversion elements 103. The lower electrode 110 is formed such that an outline thereof is in a rectangular shape (an oblong shape in the present embodiment) in the top view. An electrode equal to the electrodes 105 can be used for the lower electrode 110.

The thermoelectric conversion device 101E of the present embodiment includes a first heat transfer member 111 that is thermally connected with the plurality of thermoelectric conversion elements 103. The first heat transfer member 111 has a structure in which a first heat transfer layer 112 and a second heat transfer layer 113 are laminated in this order. For example, a material having higher thermal conductivity than air, such as aluminum oxide (Al₂O₃), silicon oxide (SiO₂), silicon nitride (SiN) or the like is used for one 112 of the first and second heat transfer layer 112 and 113. On the other hand, as a material having higher thermal conductivity than the first heat transfer layer 112, for example a metal material such as aluminum (Al) or copper (Cu) is used for the second heat transfer layer 113.

That is, in the first heat transfer member 111 of the present embodiment, the second heat transfer layer 113 has higher thermal conductivity than the first heat transfer layer 112. The first heat transfer layer 112 has an insulation property, and the second heat transfer layer 113 has electrical conductivity.

The first heat transfer layer 112 has opening portions 112a at positions corresponding to the centers of the thermoelectric conversion elements 103, and the perimeters of the opening portions 112a abut on the thermoelectric conversion elements 103 while being inclined toward the substrate 102. Thereby, the first heat transfer layer 112 (the first heat transfer member 111) is disposed at an interval S1 from some of the thermoelectric conversion elements 103 and the lower electrode 110. The interval Si may be partly different due to a difference in thickness between the thermoelectric conversion elements 103 and the lower electrode 110.

An outer circumferential portion of the first heat transfer layer 112 abuts on the first surface 102a outside the perimeters of the plurality of thermoelectric conversion elements 103 while being inclined toward the substrate 102. Thereby, the interspace between the substrate 102 and the first heat transfer layer 112 (the first heat transfer member 111) is sealed.

Furthermore, decompressed first spaces K1 are provided to the sealed interspace between the substrate 102 and the first heat transfer layer 112 (the first heat transfer member 111). That is, the decompressed first spaces K1 are provided between some of the thermoelectric conversion elements 103, the lower electrode 110, and the first heat transfer layer 112 (the first heat transfer member 111). The thermoelectric conversion device 101E of the present embodiment can also have a constitution in which the first spaces K1 are filled with a low thermal conductive material (including air) having lower thermal conductivity than the first heat transfer member 111 (the first heat transfer layer 112).

The second heat transfer layer 113 is disposed on a surface of the first heat transfer layer 112, and is formed in a rectangular shape (an oblong shape in the present embodiment) in the top view so as to overlap the lower electrode 110 in the top view. The second heat transfer layer 113 abuts on the thermoelectric conversion elements 103 in the central parts of the thermoelectric conversion elements 103 through the opening portions 112a.

Thereby, a part of the second heat transfer layer 113 forms a plurality of first heat transfer portions 111a that protrude toward a side facing the thermoelectric conversion elements 103 in a state in which the opposite side of the side facing the thermoelectric conversion elements 103 is partly recessed. The second heat transfer layer 113 (the first heat transfer member 111) is thermally connected with the thermoelectric conversion elements 103 in the central parts of the thermoelectric conversion elements 103 via the first heat transfer portions 111a.

The second heat transfer layer 113 serves as an upper electrode (center electrode) that electrically connects the plurality of thermoelectric conversion elements 103. That is, the second heat transfer layer (the upper electrode) 113 is electrically connected to the thermoelectric conversion elements 103 in the central parts of the thermoelectric conversion elements 103 via the first heat transfer portions 111a.

Thereby, the thermoelectric conversion device 101E of the present embodiment has a constitution in which the plurality of thermoelectric conversion elements 103 are connected in parallel to one another via the lower electrode 110 and the second heat transfer layer (the upper electrode) 113.

Here, in the case where the thermoelectric conversion elements 103 are formed of an n-type semiconductor, an electric current flows from the side of the lower electrode 110 acting as a cold junction toward the side of the second heat transfer layer (the upper electrode) 113 acting as a hot junction. Therefore, the thermoelectric conversion elements 103 are configured such that the electric current flows from outer circumferential sides of the thermoelectric conversion elements 103 toward central sides thereof. On the other hand, in the case where the thermoelectric conversion elements 103 are formed of a p-type semiconductor, an electric current flows from the side of the second heat transfer layer (the upper electrode) 113 acting as a hot junction toward the side of the lower electrode 110 acting as a cold junction. Therefore, the thermoelectric conversion elements 103 are configured such that the electric current flows from the central sides of the thermoelectric conversion elements 103 toward the outer circumferential sides thereof.

A part of the second heat transfer layer (the upper electrode) 113 is provided as an extension electrode 113a in a state in which it extends outside a position at which the interspace between the substrate 102 and the first heat transfer layer 112 (the first heat transfer member 111) is sealed.

The thermoelectric conversion device 101E of the present embodiment includes a second heat transfer plate 114 that is thermally connected with the thermoelectric conversion elements 103 via the substrate 102. The second heat transfer plate 114 is used as a second heat transfer member of a low temperature (heat radiation/cooling) side, and is formed of a material having higher thermal conductivity than air, and preferably a material having higher thermal conductivity than the substrate 102. As the material of this second heat transfer plate 114, a material equal to the material exemplified by the aforementioned heat transfer plate 107 can be used. The second heat transfer plate 114 may be constituted of a plurality of members.

The second heat transfer plate 114 is disposed at an interval S2 from the second surface 102b of the substrate 102, and is thermally connected with the thermoelectric conversion elements 103 via the lower electrode 110 and second heat transfer portions 114a, both of which become a cold junction side of the thermoelectric conversion elements 103.

The second heat transfer portions 114a are constituted of protrusions that protrude from a side of the second heat transfer plate 114 which faces the lower electrode 110. The second heat transfer portions 114a of the present embodiment are constituted of protrusions that protrude from a position of the second heat transfer plate 114 which faces the lower electrode 110 toward an upper side that is close to the thermoelectric conversion elements 103 (a +Z direction). A material equal to the material exemplified by the aforementioned heat transfer plate 107 can be used for the protrusions (the second heat transfer portions 114a). Further, the second heat transfer portions 114a can be formed integrally with the second heat transfer plate 114.

The second heat transfer portions 114a protrude in a region in which they overlap the lower electrode 110 in the top view, and thereby are put in a state in which tips thereof abut on the second surface 102b of the substrate 102. Thereby, the second heat transfer plate 114 is disposed at an interval S2, including the substrate 102, from the plurality of thermoelectric conversion elements 103 and the lower electrode 110, and is thermally connected with the outer circumferential sides of the thermoelectric conversion elements 103 via the lower electrode 110, the second heat transfer portions 114a, and the substrate 102, all of which become the cold junction side of the thermoelectric conversion elements 103. The interspace between the substrate 102 and the second heat transfer plate 114 is sealed with a convex 114b that protrudes from the second heat transfer plate 114 to the side of the substrate 102 in a region where it overlaps the outside from the perimeters of the plurality of thermoelectric conversion elements 103 in the top view.

Furthermore, decompressed second spaces K2 are provided to the sealed interspace between the substrate 102 and the second heat transfer plate 114. That is, the decompressed second spaces K2 are provided between the thermoelectric conversion elements 103 and the second heat transfer plate 114. The thermoelectric conversion device 101E of the present embodiment can also have a constitution in which the second spaces are filled with a low thermal conductive material (including air) having lower thermal conductivity than the second heat transfer portions 114a.

The pair of through electrodes 104e and 104f are provided in a state in which they pass through the substrate 102, the convex 114b, and the second heat transfer plate 114 in a thickness direction. One 104e of the pair of through electrodes 104e and 104f is electrically connected to the lower electrode 110, and the other through electrode 104f is electrically connected to the extension electrode 113a (the second heat transfer layer 113). Furthermore, the pair of through electrodes 104e and 104f are electrically connected to a pair of terminals 106e and 106f that are provided on a surface of the second heat transfer plate 114. The pair of through electrodes 104e and 104f and the pair of terminals 106e and 106f are electrically insulated from the convex 114b and the second heat transfer plate 114.

In the thermoelectric conversion device 101E of the present embodiment having the constitution as described above, the second heat transfer layer 113 (the first heat transfer member 111) and the thermoelectric conversion elements 103 are thermally connected with each other via the aforementioned first heat transfer portions 111a. On the other hand, the first heat transfer layer 112 (the first heat transfer member 111) is disposed at the interval Si from some of the thermoelectric conversion elements 103 and the lower electrode 110.

In the case of this constitution, heat conducted from a heat source to the first heat transfer member 111 is concentrically conducted to the central parts of the thermoelectric conversion elements 103 acting as the hot junctions via the first heat transfer portions 111a. On the other hand, the heat conducted from the heat source to the first heat transfer member 111 is hardly conducted to the outer circumference parts of the thermoelectric conversion elements 103 acting as the cold junctions. Thereby, a large difference in temperature between the hot junction and the cold junction of each of the thermoelectric conversion elements 103 is obtained, and thereby high output can be obtained.

In the thermoelectric conversion device 101E of the present embodiment, the second heat transfer plate 114 and the thermoelectric conversion elements 103 are thermally connected with each other via the aforementioned second heat transfer portions 114a. Meanwhile, the second heat transfer plate 114 is disposed at the interval S2 from the thermoelectric conversion elements 103.

In the case of this constitution, the heat can easily radiate outward from the side of the lower electrode 110 acting as the cold junction via the second heat transfer plate 114. Therefore, a large difference in temperature between the hot junction and the cold junction of each of the thermoelectric conversion elements 103 is obtained, and thereby higher output can be obtained.

In the thermoelectric conversion device 101E of the present embodiment, the substrate 102 and the first heat transfer member 111 are sealed outside the perimeters of the aforementioned plurality of thermoelectric conversion elements 103, and a sealing structure therebetween can be simplified.

Furthermore, in the thermoelectric conversion device 101E of the present embodiment, the decompressed first and second spaces K1 and K2 are provided between the aforementioned first heat transfer member 111, and some of thermoelectric conversion elements 103 and the lower electrode 110 and between the second heat transfer plate 114 and the thermoelectric conversion elements 103. The first and second spaces K1 and K2 have a function of obstructing (insulating) conduction of the heat. Thereby, higher output can be obtained while enlarging the difference in temperature between the hot junction and the cold junction of each of the thermoelectric conversion elements 103.

In the thermoelectric conversion device 101E of the present embodiment, the pair of terminals 106e and 106f can be electrically connected to the plurality of thermoelectric conversion elements 103 via the pair of through electrodes 104e and 104f that pass through the aforementioned substrate 102. Thereby, the sealing structure between the substrate 102 and the first heat transfer layer 112 (the first heat transfer member 111) can be simplified without having an influence on a sealing portion between the substrate 102 and the first heat transfer layer 112 (the first heat transfer member 111).

The second heat transfer plate 114 can also be formed in a shape suitable for heat radiation or cooling. For example, to perform air cooling on the second heat transfer plate 114, the second heat transfer plate 114 may have a constitution in which a radiation fin (a heat sink) is provided on the surface of the second heat transfer plate 114 which is located on the opposite side of the substrate 102. Further, to perform air cooling on the second heat transfer plate 114, the second heat transfer plate 114 may have a constitution in which a flow passage for circulating coolant in the second heat transfer plate 114 is provided. On the other hand, the second heat transfer plate 114 is not necessarily an essential component, and can also be omitted according to circumstances.

As described above, in the thermoelectric conversion device 101E of the present embodiment, a thermoelectric conversion characteristic of the thermoelectric conversion device 101E can be improved while simplifying the sealing structure.

The present disclosure is not necessarily limited to the above embodiments, and may be modified in various ways without departing from the spirit or teaching of the present disclosure.

For example, in the thermoelectric conversion devices 101A, 101B and 101D, the case where the heat transfer plate 107 is disposed on the high temperature (the heat source) side and the substrate 102 is disposed on the low temperature (heat radiation/cooling) side is given by way of example. However, the substrate 102 may be disposed on the high temperature (the heat source) side, and the heat transfer plate 107 may be disposed on the low temperature (heat radiation/cooling) side. Thereby, the heat from the heat source may be conducted from the side of the substrate 102. In this case, the first electrodes 105a become the hot junction side electrodes, and the second electrodes 105b become the cold junction side electrodes. Furthermore, in the thermoelectric conversion device 101E, the second heat transfer plate 114 may be disposed on the high temperature (the heat source) side, and the first heat transfer member 111 may be disposed on the low temperature (heat radiation/cooling) side. Thereby, the heat from the heat source may be conducted from the side of the second heat transfer plate 114.

Like the thermoelectric conversion devices 101B and 101C, the thermoelectric conversion device 101D may have a constitution in which the plurality of protrusions 109a and the recesses 109b, or the plurality of protrusions 109c and the recesses 109d are provided on the second surface 102b of the substrate 102.

Like the thermoelectric conversion device 101E, the thermoelectric conversion devices 101A, 101B, 101C and 101D may have a constitution in which the second heat transfer plate 114 that is thermally connected with the second surface 102b of the substrate 102 is disposed.

### Sixth Embodiment

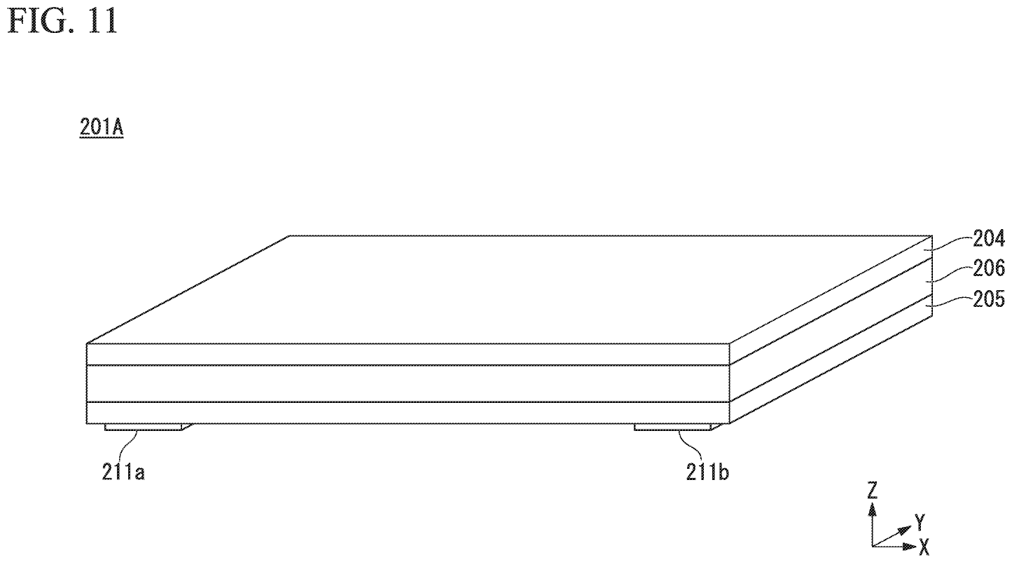

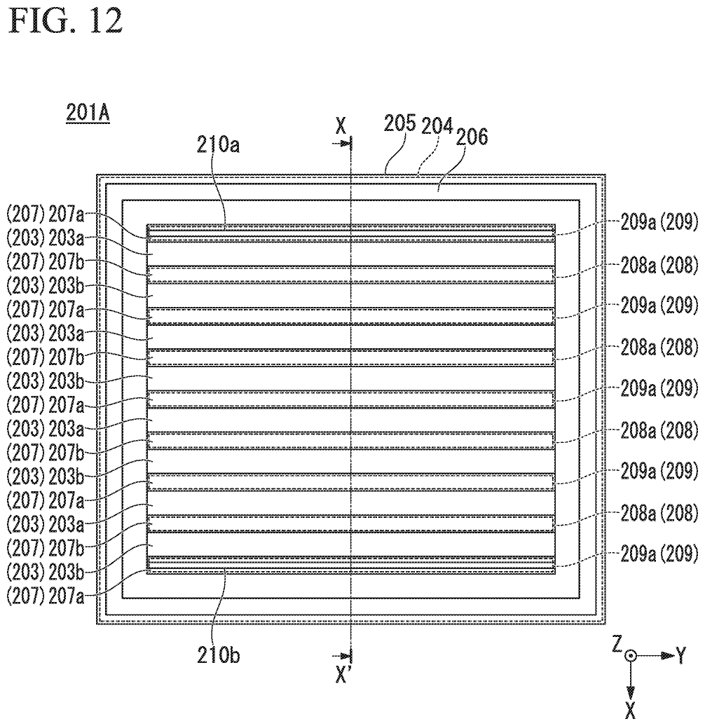

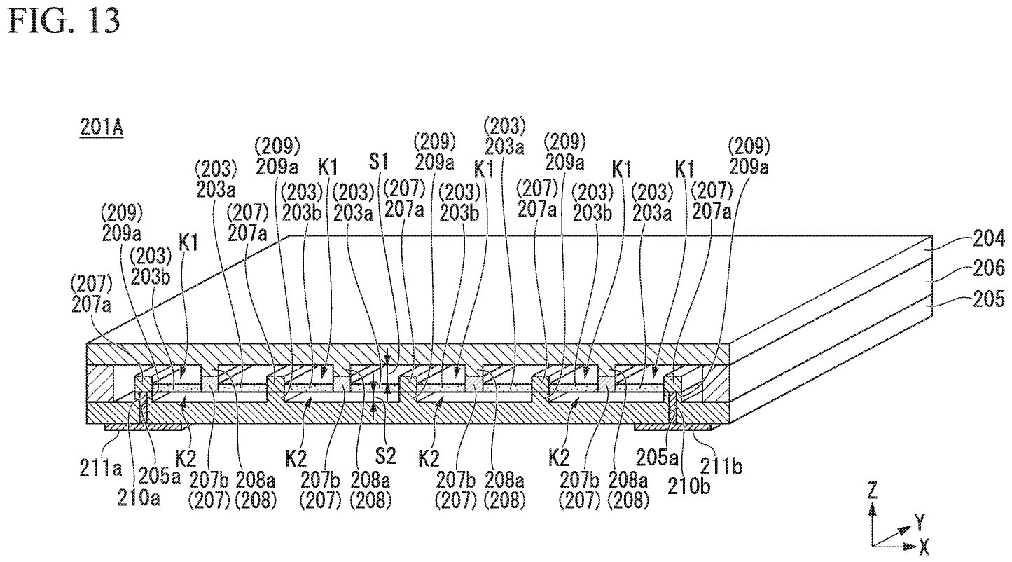

First, a thermoelectric conversion device 201A illustrated, for example, in FIGS. 11 to 13 will be described as a sixth embodiment of the present disclosure. FIG. 11 is a perspective view illustrating an appearance of the thermoelectric conversion device 201A. FIG. 12 is a perspective top view illustrating a schematic constitution of the thermoelectric conversion device 201A illustrated in FIG. 11. FIG. 13 is a sectional perspective view of the thermoelectric conversion device 201A taken along line X-X′ illustrated in FIG. 12.

The drawings illustrated below sets an XYZ orthogonal coordinate system, and indicates the X-axial direction as a first direction in a specific surface of the thermoelectric conversion device 201A, the Y-axial direction as a second direction in the specific plane of the thermoelectric conversion device 201A, and the Z-axial direction as a thickness direction (a height direction) orthogonal to the specific plane of the thermoelectric conversion device 201A.

As illustrated in FIGS. 11 to 13, the thermoelectric conversion device 201A of the present embodiment has a structure in which a plurality of thermoelectric conversion elements 203 (eight thermoelectric conversion elements in the present embodiment) that are disposed in a row in the specific plane thereof are interposed between a first heat transfer plate 204 and a second heat transfer plate 205. Further, the thermoelectric conversion device 201A has a structure in which the first heat transfer plate 204 and the second heat transfer plate 205 are sealed outside the perimeters of the plurality of thermoelectric conversion elements 203 via a sealing member 206.

Of the first and second directions that intersect each other (are orthogonal to each other in the present embodiment) in the specific plane, the first direction is set to a transverse direction, and the second direction is set to a longitudinal direction. The plurality of thermoelectric conversion elements 203 are disposed in a row at fixed intervals in the first direction. The thermoelectric conversion elements 203 are mutually formed in the same size in a rectangular shape (an oblong shape in the present embodiment) in the top view.

The plurality of thermoelectric conversion elements 203 have a constitution in which first thermoelectric conversion elements (one thermoelectric conversion elements) 203a formed of any one of p-type and n-type semiconductors (an n-type semiconductor in the present embodiment) and second thermoelectric conversion elements (the other thermoelectric conversion elements) 203b formed of the other of the p-type and n-type semiconductors (the p-type semiconductor in the present embodiment) are alternately disposed in a row.

A multilayer film of an n-type silicon (Si) film and an n-type silicon germanium (SiGe) alloy film on which, for example, antimony (Sb) of a high concentration (10¹⁸ to 10¹⁹ cm⁻³) is doped can be used for the first thermoelectric conversion elements 203a. In the first thermoelectric conversion elements 203a formed of an n-type semiconductor, an electric current flows from a cold junction side toward a hot junction side.

A multilayer film of a p-type silicon (Si) film and a p-type silicon germanium (SiGe) alloy film on which, for example, boron (B) of a high concentration (10¹⁸ to 10¹⁹ cm⁻³) is doped can be used for the second thermoelectric conversion elements 203b. In the second thermoelectric conversion elements 203b formed of a p-type semiconductor, an electric current flows from a hot junction side toward a cold junction side.

The thermoelectric conversion elements 203 are not necessarily limited to those formed of the aforementioned multilayer film of the p-type or n-type semiconductor, and may be those formed of a single layer film of the p-type or n-type semiconductor. An oxide-based semiconductor can be used as the semiconductor. A thermoelectric conversion film formed of an organic polymer film or a metal film may be used. Furthermore, the thermoelectric conversion elements 203 are not limited to the aforementioned thermoelectric conversion film, and may use a bulk.

The thermoelectric conversion device 201A of the present embodiment includes a plurality of electrodes 207 (nine electrodes in the present embodiment) that are provided in a row in an array direction (the first direction) of the plurality of thermoelectric conversion elements 203 in order to connect the plurality of thermoelectric conversion elements 203 to one another in series.

The plurality of thermoelectric conversion elements 203 are disposed between first electrodes 207a and second electrodes 207b that are alternately adjacent to each other in the array direction of the plurality of electrodes 207, and are electrically connected to the first electrodes 207a and the second electrodes 207b.

The plurality of electrodes 207 are mutually formed in the same size in a rectangular shape (an oblong shape in the present embodiment) in the top view over the entire region in the longitudinal direction (the second direction) of the thermoelectric conversion elements 203 in a state in which they are in contact with lateral surfaces of one end sides and the other end sides of the thermoelectric conversion elements 203 which face each other in the first direction. For example, copper (Cu) or gold (Au) in which electrical conductivity and thermal conductivity are high and shape machining is easy can be appropriately used for the electrodes 207.

The plurality of electrodes 207 have a constitution in which the five first electrodes 207a serving as cold junction side electrodes and the four second electrodes 207b serving as hot junction side electrodes are alternately disposed in a row. The first electrodes 207a are disposed on one end side (a +X side in the present embodiment) of each of the first thermoelectric conversion elements 203a and one end side (a −X side in the present embodiment) of each of the second thermoelectric conversion elements 203b. On the other hand, the second electrodes 207b are disposed on the other end side (the −X side in the present embodiment) of each of the first thermoelectric conversion elements 203a and the other end side (the +X side in the present embodiment) of each of the second thermoelectric conversion elements 203b. That is, in the thermoelectric conversion device 201A of the present embodiment, the one end side of each of the first thermoelectric conversion elements 203a becomes the +X side, and the other end side of each of the first thermoelectric conversion elements 203a becomes the −X side. On the other hand, the one end side of each of the second thermoelectric conversion elements 203b becomes the −X side, and the other end sides of each of the second thermoelectric conversion elements 203b becomes the +X side.

In the first thermoelectric conversion elements 203a formed of the n-type semiconductor, an electric current flows from the side of the first electrodes 207a acting as cold junctions toward the side of the second electrodes 207b acting as hot junctions. On the other hand, in the second thermoelectric conversion elements 203b formed of the p-type semiconductor, an electric current flows from the side of the second electrodes 207b acting as hot junctions toward the side of the first electrodes 207a acting as cold junctions.

Therefore, in the thermoelectric conversion device 201A of the present embodiment, a direction of the electric current flowing to the first thermoelectric conversion elements 203a and a direction of the electric current flowing to the second thermoelectric conversion elements 203b are equal to each other.

The first heat transfer plate 204 acts as a first heat transfer member of the high temperature (the heat source) side, and is disposed on one side across the specific plane within which the plurality of thermoelectric conversion elements 203 and the electrodes 207 stand side by side. The first heat transfer plate 204 is formed of a material having higher thermal conductivity than air. Metals are preferably used as the material of this first heat transfer plate 204, and among them, particularly for example aluminum (Al) or copper (Cu) in which thermal conductivity is high and shape machining is easy can be appropriately used. A ceramic material such as aluminum oxide (Al₂O₃) can be used as the material of the first heat transfer plate 204. The first heat transfer plate 204 may be constituted of a plurality of members.

The first heat transfer plate 204 are disposed at an interval Si from the plurality of thermoelectric conversion elements 203 and the first electrodes 207a, and is thermally connected with the thermoelectric conversion elements 203 via the second electrodes 207b and first heat transfer portions 208, both of which become the hot junction sides of the thermoelectric conversion elements 203. The interval Si may be partly different by a difference in thickness between the thermoelectric conversion elements 203 and the first electrodes 207a.

The first heat transfer portions 208 are formed by protrusions 208a that protrude from any one of surfaces of the first heat transfer plate 204 and the second electrodes 207b which face each other. The first heat transfer portions 208 of the present embodiment are formed by the protrusions 208a that protrude from positions of the first heat transfer plate 204 which face the second electrodes 207b toward a lower side that is the side of the thermoelectric conversion elements 203 (in the −Z direction). The protrusions 208a (the first heat transfer portions 208) can use a material equal to the material exemplified by the aforementioned first heat transfer plate 204. The first heat transfer portions 208 can be formed integrally with the first heat transfer plate 204.

Each of the protrusions 208a has a rectangular shape (an oblong shape in the present embodiment) in the top view, and is provided to protrude in a region in which it overlaps each of the second electrodes 207b in the top view. The protrusions 208a by which the first heat transfer portions 208 are formed are put in a state in which tips thereof abut on the second electrodes 207b. Thereby, the first heat transfer plate 204 is thermally connected with the other end sides of the thermoelectric conversion elements 203 (the −X sides of the first thermoelectric conversion elements 203a and the +X sides of the second thermoelectric conversion elements 203b) via the protrusions 208a (the first heat transfer portions 208). The tip of each of the protrusions 208a is thermally connected with each of the second electrodes 207b via an insulating layer (not shown) in a state in which it is electrically insulated from each of the second electrodes 207b. Thereby, first spaces K1 are each provided between the protrusions 208a (the first heat transfer portions 208) adjacent to each other.

An insulating material having higher thermal conductivity than air, such as, for example, aluminum oxide (Al₂O₃), silicon oxide (SiO₂), silicon nitride (SiN), or aluminum nitride (AlN) can be used for the insulating layer as the material of which a part of each of the first heat transfer portions 208 is formed. For example, a UV curable resin, a silicone-based resin, or thermal conductive grease (for example, silicone-based grease or non-silicone-based grease containing a metal oxide) can be used. In the case where electric insulation does not become problematic between the tips of the protrusions 208a and the second electrodes 207b, the tips of the protrusions 208a and the second electrodes 207b may be directly connected with each other without providing the aforementioned insulating layers.

Further, the first heat transfer portions 208 are not limited to the case where they are formed by the protrusions 208a protruding from the side of the aforementioned first heat transfer plate 204, and may be formed by protrusions that protrude from the side of the second electrodes 207b toward an upper side that is the side of the first heat transfer plate 204 (in the +Z direction). These protrusions can be formed, for example, by making thicknesses of the second electrodes 207b larger than those of the thermoelectric conversion elements 203, and the first heat transfer plate 204 and the thermoelectric conversion elements 203 (the second electrodes 207b) can also be thermally connected with each other via these protrusions. Furthermore, other members (including the above insulating layers) that are thermally connected between the first heat transfer plate 204 and the thermoelectric conversion elements 203 (the second electrodes 207b) can also be provided as the first heat transfer portions 208.

The second heat transfer plate 205 is used as a second heat transfer member of a low temperature (heat radiation/cooling) side, and is disposed on the other side across the specific plane within which the plurality of thermoelectric conversion elements 203 and the electrodes 207 stand side by side. The second heat transfer plate 205 is formed of a material having higher thermal conductivity than air. As the material of this second heat transfer plate 205, a material equal to the material exemplified by the aforementioned first heat transfer plate 204 can be used. The second heat transfer plate 205 may be constituted of a plurality of members.

The second heat transfer plate 205 are disposed at an interval S2 from the plurality of thermoelectric conversion elements 203 and the second electrodes 207b, and is thermally connected with the thermoelectric conversion elements 203 via the first electrodes 207a and second heat transfer portions 209, both of which become the cold junction sides of the thermoelectric conversion elements 203. The interval S2 may be partly different by a difference in thickness between the thermoelectric conversion elements 203 and the second electrodes 207b.

The second heat transfer portions 209 are formed by protrusions 209a that protrude from any one of surfaces of the second heat transfer plate 205 and the first electrodes 207a which face each other. The second heat transfer portions 209 of the present embodiment are formed by the protrusions 209a that protrude from positions of the second heat transfer plate 205 which face the first electrodes 207a toward an upper side that is the side of the thermoelectric conversion elements 203 (in the +Z direction). The protrusions 209a (the second heat transfer portions 209) can use a material equal to the material exemplified by the aforementioned first heat transfer plate 204. The second heat transfer portions 209 can be formed integrally with the second heat transfer plate 205.

Each of the protrusions 209a has a rectangular shape (an oblong shape in the present embodiment) in the top view, and is provided to protrude in a region in which it overlaps each of the first electrodes 207a in the top view. The protrusions 209a by which the second heat transfer portions 209 are formed are put in a state in which tips thereof abut on the first electrodes 207a. Thereby, the second heat transfer plate 205 is thermally connected with the one end sides of the thermoelectric conversion elements 203 (the +X sides of the first thermoelectric conversion elements 203a and the −X sides of the second thermoelectric conversion elements 203b) via the protrusions 209a (the second heat transfer portions 209). The tip of each of the protrusions 209a is thermally connected with each of the first electrodes 207a via an insulating layer (not shown) in a state in which it is electrically insulated from each of the first electrodes 207a. Thereby, second spaces K2 are each provided between the protrusions 209a (the second heat transfer portions 209) adjacent to each other.

An insulating layer equal to the insulating layer exemplified by each of the aforementioned first heat transfer portions 208 can be used for the insulating layer as the insulating layer constituting a part of each of the second heat transfer portions 209. In the case where electric insulation does not become problematic between the tips of the protrusions 209a and the first electrodes 207a, the tips of the protrusions 209a and the first electrodes 207a may be directly connected with each other without providing the aforementioned insulating layers.

Further, the second heat transfer portions 209 are not limited to the case where they are formed by the protrusions 209a protruding from the side of the aforementioned second heat transfer plate 205, and may be formed by protrusions that protrude from the side of the first electrodes 207a toward an lower side that is the side of the second heat transfer plate 205 (in the −Z direction). These protrusions can be formed, for example, by making thicknesses of the first electrodes 207a larger than those of the thermoelectric conversion elements 203, and the second heat transfer plate 205 and the thermoelectric conversion elements 203 (the first electrodes 207a) can also be thermally connected with each other via these protrusions. Furthermore, other members (including the above insulating layers) that are thermally connected between the second heat transfer plate 205 and the thermoelectric conversion elements 203 (the first electrodes 207a) can also be provided as the second heat transfer portions 209.

The sealing member 206 is formed of, for example, an adhesive resistant to a high temperature such as a silicone-based adhesive, and is sealed to surround a perimeter between the first heat transfer plate 204 and the second heat transfer plate 205.

Further, the first and second spaces K1 and K2, each of which is decompressed, are provided between the first heat transfer plate 204 and the second heat transfer plate 205 that are sealed with the sealing member 206. That is, the decompressed first spaces K1 are provided between the thermoelectric conversion elements 203 and the first electrodes 207a, and the first heat transfer plate 204. On the other hand, the decompressed second spaces K2 are provided between the thermoelectric conversion elements 203 and the second electrodes 207b, and the second heat transfer plate 205.

The decompressed first and second spaces K1 and K2 can be formed using a method of sealing the first heat transfer plate 204 and the second heat transfer plate 205 with the sealing member 206 under a decompressed atmosphere, a method of providing a hole in a part of the sealing member 206 and sealing the hole after the first and second spaces K1 and K2 are decompressed through the hole, or the like. The thermoelectric conversion device 201A of the present embodiment can also have a constitution in which the first spaces K1 are filled with a low thermal conductive material (including air) having lower thermal conductivity than the first heat transfer portions 208 or the second spaces K2 are filled with a low thermal conductive material (including air) having lower thermal conductivity than the second heat transfer portions 209.

The thermoelectric conversion device 201A of the present embodiment includes a pair of through electrodes 210a and 210b that pass through at least one of the first heat transfer plate 204 and the second heat transfer plate 205 (the second heat transfer plate 205 in the present embodiment) in a thickness direction. The thermoelectric conversion device 201A has a structure in which the plurality of thermoelectric conversion elements 203 are connected in series between the pair of through electrodes 210a and 210b.

The pair of through electrodes 210a and 210b are mutually formed in the same size in a rectangular shape (an oblong shape in the present embodiment) in the top view so as to be connected over the entire region in a longitudinal direction (the second direction) thereof in the middle portions of the first electrodes 207a located at opposite ends in the array direction (the first direction) of the thermoelectric conversion elements 203.

Further, the pair of through electrodes 210a and 210b are provided in a state in which they are embedded in holes 205a that pass through the protrusions 209a (the second heat transfer portions 209) and the second heat transfer plate 205 in the thickness direction by through-hole plating or the like. For example, copper (Cu) or gold (Au) can be appropriately used for the pair of through electrodes 210a and 210b as a conductive material that can be embedded in these holes 205a. The pair of through electrodes 210a and 210b are not limited to a state in which they are embedded in the holes 205a in a solid form, and can also put in a state in which they are embedded in circumferences of the holes 205a in a hollow form.

Thereby, one 210a of the pair of through electrodes 210a and 210b is electrically connected to the first electrodes 207a that is disposed on the −X sides of the thermoelectric conversion element 203 (the second thermoelectric conversion element 203b in the present embodiment) located on one endmost side (the −X side) in the array direction (the first direction) of the thermoelectric conversion elements 203. In contrast, the other through electrode 210b is electrically connected to the first electrode 207a that is disposed on the +X sides of the thermoelectric conversion element 203 (the first thermoelectric conversion element 203a in the present embodiment) located on the other endmost side (the +X side) in the array direction (the first direction) of the thermoelectric conversion elements 203.

Furthermore, the pair of through electrodes 210a and 210b are electrically connected to a pair of terminals 211a and 211b provided on a surface of the second heat transfer plate 205 which is located on the opposite side of a surface facing the plurality of thermoelectric conversion elements 203. The pair of terminals 211a and 211b are mutually formed in the same size in a rectangular shape (an oblong shape in the present embodiment) in the top view so as to be located at opposite ends of the second heat transfer plate 205 in the first direction and be connected to the pair of through electrodes 210a and 210b over the entire region in the second direction. The same thing as the electrodes 207 may be used for the pair of terminals 211a and 211b. Further, the pair of through electrodes 210a and 210b and the pair of terminals 211a and 211b are electrically insulated from the protrusions 209a (the second heat transfer portions 209) and the second heat transfer plate 205.

Thereby, one 211a of the pair of terminals 211a and 211b is electrically connected to the first electrode 207a that is disposed on the −X sides of the thermoelectric conversion elements 203 (the second thermoelectric conversion elements 203b in the present embodiment) located on one endmost side (the −X side) in the array direction (the first direction) of the thermoelectric conversion elements 203 via one of the through electrodes 210a. In contrast, the other terminal 211b is electrically connected to the first electrode 207a that is disposed on the +X sides of the thermoelectric conversion elements 203 (the first thermoelectric conversion elements 203a in the present embodiment) located on the other endmost side (the +X side) in the array direction (the first direction) of the thermoelectric conversion elements 203 via the other through electrode 210b.

In the thermoelectric conversion device 201A of the present embodiment having the constitution as described above, the first heat transfer plate 204 is disposed on a high temperature (a heat source) side, and the second heat transfer plate 205 is disposed to be a low temperature (heat radiation/cooling) side. Thereby, heat conducted from the heat source (not shown) to the first heat transfer plate 204 is conducted to the second electrodes 207b via the first heat transfer portions 208 (the protrusions 208a), and thereby the side of the second electrodes 207b of the thermoelectric conversion elements 203 becomes relatively a high temperature.

Meanwhile, since the heat conducted to the thermoelectric conversion elements 203 radiates outward from the side of the first electrodes 207a of the thermoelectric conversion elements 203 and then the side of the second heat transfer plate 205 via the second heat transfer portions 209 (the protrusions 209a), the side of the first electrodes 207a of the thermoelectric conversion elements 203 becomes relatively a low temperature. Therefore, a difference in temperature between the first electrodes 207a and the second electrodes 207b of the thermoelectric conversion elements 203 occurs.

Thereby, movement of charges (carriers) between the first electrodes 207a and the second electrodes 207b of the thermoelectric conversion elements 203 occurs. That is, electromotive forces (voltages) are generated between the first electrodes 207a and the second electrodes 207b of the thermoelectric conversion elements 203 due to a Seebeck effect.

Here, although the electromotive force (the voltage) generated from one of the thermoelectric conversion elements 203 is small, the plurality of thermoelectric conversion elements 203 are connected in series between the pair of terminals 211a and 211b via the pair of through electrodes 210a and 210b. Therefore, a relatively high voltage can be taken out between the pair of terminals 211a and 211b as the sum of the electromotive forces.

In the thermoelectric conversion device 201A of the present embodiment, the first heat transfer plate 204 and the thermoelectric conversion elements 203 are thermally connected with each other via the aforementioned first heat transfer portions 208 (the protrusions 208a). Meanwhile, the first heat transfer plate 204 is disposed at the interval Si from the thermoelectric conversion elements 203 and the first electrodes 207a.

In the case of this constitution, the heat conducted from the heat source to the first heat transfer plate 204 is concentrically conducted to the second electrodes 207b acting as the hot junctions via the first heat transfer portions 208 (the protrusions 208a). On the other hand, the heat conducted from the heat source to the first heat transfer plate 204 is hardly conducted to the first electrodes 207a acting as the cold junctions. Thereby, a large difference in temperature between the hot junction and the cold junction of each of the thermoelectric conversion elements 203 is obtained, and thereby high output can be obtained.

In the thermoelectric conversion device 201A of the present embodiment, the second heat transfer plate 205 and the thermoelectric conversion elements 203 are thermally connected with each other via the aforementioned second heat transfer portions 209 (the protrusions 209a). Meanwhile, the second heat transfer plate 205 is disposed at the interval S2 from the thermoelectric conversion elements 203 and the second electrodes 207b.

Thereby, the heat can easily radiate outward from the side of the first electrodes 207a acting as the cold junctions via the second heat transfer plate 205. Therefore, a large difference in temperature between the hot junction and the cold junction of each of the thermoelectric conversion elements 203 is obtained, and thereby higher output can be obtained.

In the thermoelectric conversion device 201A of the present embodiment, the first heat transfer plate 204 and the second heat transfer plate 205 are sealed outside the perimeters of the aforementioned plurality of thermoelectric conversion elements 203, and a sealing structure therebetween can be simplified.

Furthermore, in the thermoelectric conversion device 201A of the present embodiment, the decompressed first and second spaces K1 and K2 are provided between the aforementioned first heat transfer plate 204, and the thermoelectric conversion elements 203 and the first electrodes 207a and between the second heat transfer plate 205, and the thermoelectric conversion elements 203 and the second electrodes 207b. The first and second spaces K1 and K2 have a function of obstructing (insulating) conduction of the heat. Thereby, higher output can be obtained while enlarging the difference in temperature between the hot junction and the cold junction of each of the thermoelectric conversion elements 203.

In the thermoelectric conversion device 201A of the present embodiment, the pair of terminals 211a and 211b can be electrically connected to the plurality of thermoelectric conversion elements 203 via the pair of through electrodes 210a and 210b that pass through the aforementioned second heat transfer plate 205. Thereby, the sealing structure between the first heat transfer plate 204 and the second heat transfer plate 205 can be simplified without having an influence on a sealing portion between the first heat transfer plate 204 and the second heat transfer plate 205 (a portion where the sealing member 206 is provided).

As described above, in the thermoelectric conversion device 201A of the present embodiment, a thermoelectric conversion characteristic of the thermoelectric conversion device 201A can be improved while simplifying the sealing structure.

### Seventh Embodiment

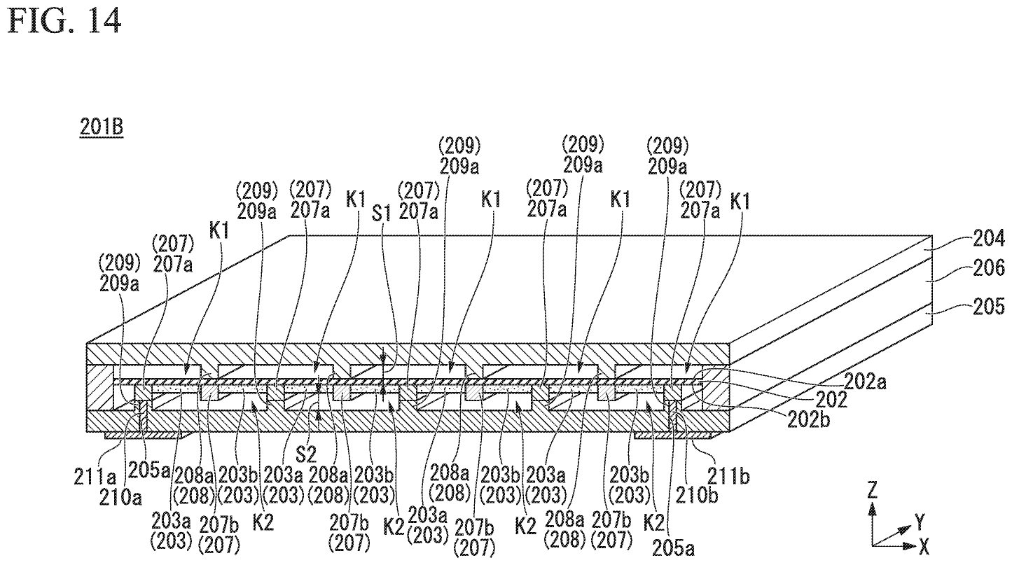

Next, a thermoelectric conversion device 201B illustrated, for example, in HG 14 will be described as a seventh embodiment of the present disclosure. FIG. 14 is a sectional perspective view illustrating a schematic constitution of the thermoelectric conversion device 201B. Further, in the following description, with respect to parts equivalent to those of the thermoelectric conversion device 201A, description will be omitted, and the same reference signs will be given in the drawing.

As illustrated in FIG. 14, the thermoelectric conversion device 201B of the present embodiment has a constitution in which a substrate 202 on which a plurality of thermoelectric conversion elements 203 are disposed is sandwiched between a first heat transfer plate 204 and a second heat transfer plate 205. Further, the thermoelectric conversion device 201B has a constitution in which the first heat transfer plate 204 and the second heat transfer plate 205 are sealed outside the perimeter of the substrate 202 via a sealing member 206.

The substrate 202 is formed of an insulating base that has a first surface (an upper surface in the present embodiment) 202a and a second surface (a lower surface in the present embodiment) 202b that face each other in a thickness direction. For example, a high-resistance silicon (Si) substrate having sheet resistance of 10Ω or higher is preferably used as the substrate 202. The sheet resistance of the substrate 202 is 10Ω or higher, so that an electric short circuit can be prevented from occurring between a plurality of thermoelectric conversion elements 203.

In addition to the aforementioned high-resistance Si substrate, for example a silicon on insulator (SOI) substrate having an oxide insulating layer inside the substrate, a ceramic substrate, a glass substrate, or a high-resistance single crystal substrate other than them can be used as the substrate 202. Furthermore, even if the substrate 202 is a low-resistance substrate having sheet resistance of 10Ω or lower, a substrate in which a high-resistance material is disposed between this low-resistance substrate and the thermoelectric conversion elements 203 can be used as the substrate 202.

In the thermoelectric conversion device 201B of the present embodiment, the plurality of thermoelectric conversion elements 203 and electrodes 207 are alternately provided on a surface of the second surface 202b. For this reason, protrusions 208a by which first heat transfer portions 208 are formed protrude in a region in which they overlap second electrodes 207b in the top view, and thereby are put in a state in which tips thereof abut on the second electrodes 207b via the substrate 202. Thereby, the first heat transfer plate 204 is disposed at an interval S1, including the substrate 202, from the plurality of thermoelectric conversion elements 203 and first electrodes 207a, and is thermally connected with the thermoelectric conversion elements 203 via the second electrodes 207b, the protrusions 208a (the first heat transfer portions 208), and the substrate 202, all of which become hot junction sides of the thermoelectric conversion elements 203. Further, the first heat transfer plate 204 is thermally connected with the other end sides of the thermoelectric conversion elements 203 (−X sides of first thermoelectric conversion elements 203a and +X sides of second thermoelectric conversion elements 203b) via the protrusions 208a (the first heat transfer portions 208).

Further, decompressed first spaces K1 are provided between the first heat transfer plate 204 and the first surface 202a of the substrate 202. On the other hand, decompressed second spaces K2 are provided between the second heat transfer plate 205, and the plurality of thermoelectric conversion elements 203 and the second electrodes 207b. The thermoelectric conversion device 201B of the present embodiment can also have a constitution in which the first spaces K1 are filled with a low thermal conductive material (including air) having lower thermal conductivity than the first heat transfer portions 208 and the second spaces K2 are filled with a low thermal conductive material (including air) having lower thermal conductivity than second heat transfer portions 209.

In the thermoelectric conversion device 201B of the present embodiment having the constitution as described above, the first heat transfer plate 204 and the thermoelectric conversion elements 203 are thermally connected with each other via the aforementioned first heat transfer portions 208 (the protrusions 208a) and the aforementioned substrate 202. Meanwhile, the first heat transfer plate 204 is disposed at an interval Si from the thermoelectric conversion elements 203 and the first electrodes 207a.

In the case of this constitution, heat conducted from a heat source to the first heat transfer plate 204 is concentrically conducted to the second electrodes 207b acting as hot junctions via the first heat transfer portions 208 (the protrusions 208a). On the other hand, the conducted from the heat source to the first heat transfer plate 204 is hardly conducted to the first electrodes 207a acting as cold junctions. Thereby, a large difference in temperature between the hot junction and the cold junction of each of the thermoelectric conversion elements 203 is obtained, and thereby high output can be obtained.

In the thermoelectric conversion device 201B of the present embodiment, the second heat transfer plate 205 and the thermoelectric conversion elements 203 are thermally connected with each other via the aforementioned second heat transfer portions 209 (the protrusions 209a). Meanwhile, the second heat transfer plate 205 is disposed at an interval S2 from the thermoelectric conversion elements 203 and the second electrodes 207b.

Thereby, the heat can easily radiate outward from the side of the first electrodes 207a acting as the cold junctions via the second heat transfer plate 205. Therefore, a large difference in temperature between the hot junction and the cold junction of each of the thermoelectric conversion elements 203 is obtained, and thereby higher output can be obtained.

In the thermoelectric conversion device 201B of the present embodiment, the first heat transfer plate 204 and the second heat transfer plate 205 are sealed outside the perimeter of the substrate 202 on which the aforementioned plurality of thermoelectric conversion elements 203 are provided, and a sealing structure therebetween can be simplified.

Furthermore, in the thermoelectric conversion device 201B of the present embodiment, the decompressed first and second spaces K1 and K2 are provided between and between the second heat transfer plate 205, and the thermoelectric conversion elements 203 and the second electrodes 207b in a region in which the aforementioned first heat transfer plate 204 overlaps the thermoelectric conversion elements 203 of the substrate 202 and the first electrodes 207a in the top view. The first and second spaces K1 and K2 have a function of obstructing (insulating) conduction of the heat. Thereby, higher output can be obtained while enlarging the difference in temperature between the hot junction and the cold junction of each of the thermoelectric conversion elements 203.

In the thermoelectric conversion device 201B of the present embodiment, the pair of terminals 211a and 211b can be electrically connected to the plurality of thermoelectric conversion elements 203 via the pair of through electrodes 210a and 210b that pass through the aforementioned second heat transfer plate 205. Thereby, the sealing structure between the first heat transfer plate 204 and the second heat transfer plate 205 can be simplified without having an influence on a sealing portion between the first heat transfer plate 204 and the second heat transfer plate 205 (a portion where the sealing member 206 is provided).

As described above, in the thermoelectric conversion device 201B of the present embodiment, a thermoelectric conversion characteristic of the thermoelectric conversion device 201B can be improved while simplifying the sealing structure.

### Eighth Embodiment

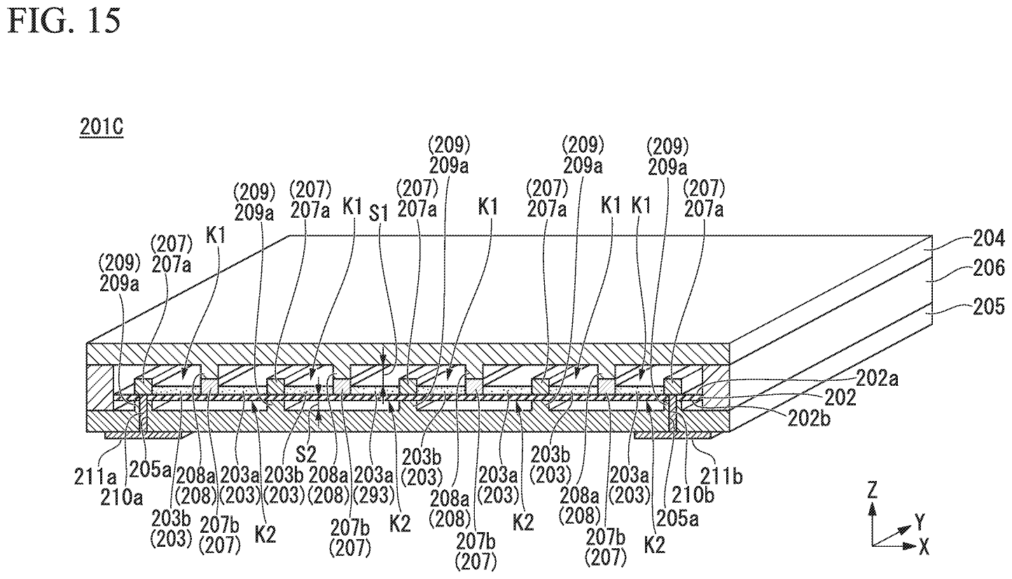

Next, a thermoelectric conversion device 201C illustrated, for example, in FIG. 15 will be described as an eighth embodiment of the present disclosure. FIG. 15 is a sectional perspective view illustrating a schematic constitution of the thermoelectric conversion device 201C. Further, in the following description, with respect to parts equivalent to those of the thermoelectric conversion device 201B, description will be omitted, and the same reference signs will be given in the drawing.

As illustrated in FIG. 15, like the thermoelectric conversion device 201B, the thermoelectric conversion device 201C of the present embodiment has a constitution in which a substrate 202 on which a plurality of thermoelectric conversion elements 203 are disposed is sandwiched between a first heat transfer plate 204 and a second heat transfer plate 205. Further, the thermoelectric conversion device 201C has a constitution in which the first heat transfer plate 204 and the second heat transfer plate 205 are sealed outside the perimeter of the substrate 202 via a sealing member 206.

In the thermoelectric conversion device 201C of the present embodiment, contrary to the thermoelectric conversion device 201B, the plurality of thermoelectric conversion elements 203 and electrodes 207 are alternately provided in a row on a surface of a first surface 202a. For this reason, protrusions 209a by which second heat transfer portions 209 are formed protrude in a region in which they overlap first electrodes 207a in the top view, and thereby are put in a state in which tips thereof abut on the first electrodes 207a via the substrate 202. Thereby, the second heat transfer plate 205 is disposed at an interval S2, including the substrate 202, from the plurality of thermoelectric conversion elements 203 and first electrodes 207a, and is thermally connected with the thermoelectric conversion elements 203 via the first electrodes 207a, the protrusions 209a (the second heat transfer portions 209), and the substrate 202, all of which become cold junction sides of the thermoelectric conversion elements 203. Further, the second heat transfer plate 205 is thermally connected with one end sides of the thermoelectric conversion elements 203 (+X sides of first thermoelectric conversion elements 203a and −X sides of second thermoelectric conversion elements 203b) via the protrusions 209a (the second heat transfer portions 209).

Further, decompressed first spaces K1 are provided between the first heat transfer plate 204, and the plurality of thermoelectric conversion elements 203 and the first electrodes 207a. On the other hand, decompressed second spaces K2 are provided between the second heat transfer plate 205 and a second surface 202b of the substrate 202.

The thermoelectric conversion device 201C of the present embodiment can also have a constitution in which the first spaces K1 are filled with a low thermal conductive material (including air) having lower thermal conductivity than first heat transfer portions 208 and the second spaces K2 are filled with a low thermal conductive material (including air) having lower thermal conductivity than the second heat transfer portions 209.

Furthermore, a pair of through electrodes 210a and 210b are provided in a state in which they pass through the protrusions 209a (the second heat transfer portions 209), the second heat transfer plate 205, and the substrate 202 in a thickness direction.

In the thermoelectric conversion device 201C of the present embodiment having the constitution as described above, the first heat transfer plate 204 and the thermoelectric conversion elements 203 are thermally connected with each other via the aforementioned first heat transfer portions 208 (the protrusions 208a). Meanwhile, the first heat transfer plate 204 is disposed at an interval Si from the thermoelectric conversion elements 203 and the first electrodes 207a.

In the case of this constitution, heat conducted from a heat source to the first heat transfer plate 204 is concentrically conducted to the second electrodes 207b acting as hot junctions via the first heat transfer portions 208 (the protrusions 208a). On the other hand, the conducted from the heat source to the first heat transfer plate 204 is hardly conducted to the first electrodes 207a acting as cold junctions. Thereby, a large difference in temperature between the hot junction and the cold junction of each of the thermoelectric conversion elements 203 is obtained, and thereby high output can be obtained.

In the thermoelectric conversion device 201C of the present embodiment, the second heat transfer plate 205 and the thermoelectric conversion elements 203 are thermally connected with each other via the aforementioned second heat transfer portions 209 (the protrusions 209a) and the substrate 202. Meanwhile, the second heat transfer plate 205 is disposed at an interval S2 from the thermoelectric conversion elements 203 and the second electrodes 207b.

Thereby, the heat can easily radiate outward from the side of the first electrodes 207a acting as the cold junctions via the second heat transfer plate 205. Therefore, a large difference in temperature between the hot junction and the cold junction of each of the thermoelectric conversion elements 203 is obtained, and thereby higher output can be obtained.

In the thermoelectric conversion device 201C of the present embodiment, the first heat transfer plate 204 and the second heat transfer plate 205 are sealed outside the perimeter of the substrate 202 on which the aforementioned plurality of thermoelectric conversion elements 203 are provided, and a sealing structure therebetween can be simplified.

Furthermore, in the thermoelectric conversion device 201C of the present embodiment, the decompressed first and second spaces K1 and K2 are provided between the aforementioned first heat transfer plate 204, and the thermoelectric conversion elements 203 and the first electrodes 207a and between the second heat transfer plate 205, and the thermoelectric conversion elements 203 of the substrate 202 and the second electrodes 207b. The first and second spaces K1 and K2 have a function of obstructing (insulating) conduction of the heat. Thereby, higher output can be obtained while enlarging the difference in temperature between the hot junction and the cold junction of each of the thermoelectric conversion elements 203.

In the thermoelectric conversion device 201C of the present embodiment, a pair of terminals 211a and 211b can be electrically connected to the plurality of thermoelectric conversion elements 203 via the pair of through electrodes 210a and 210b that pass through the aforementioned second heat transfer plate 205 and the substrate 202. Thereby, the sealing structure between the first heat transfer plate 204 and the second heat transfer plate 205 can be simplified without having an influence on a sealing portion between the first heat transfer plate 204 and the second heat transfer plate 205 (a portion where the sealing member 206 is provided).

As described above, in the thermoelectric conversion device 201C of the present embodiment, a thermoelectric conversion characteristic of the thermoelectric conversion device 201C can be improved while simplifying the sealing structure.

### Ninth Embodiment

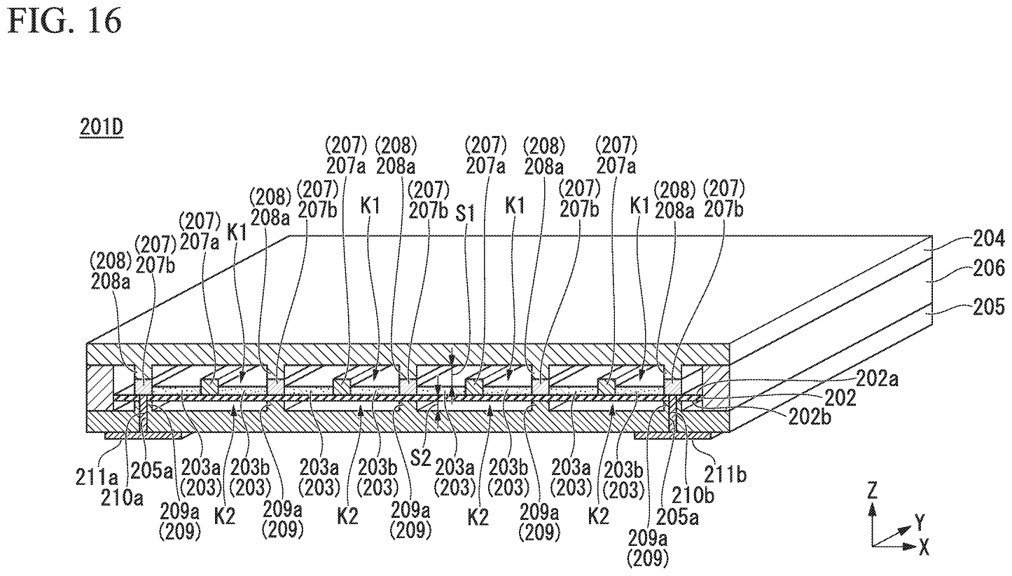

Next, a thermoelectric conversion device 201D illustrated, for example, in FIG. 16 will be described as a ninth embodiment of the present disclosure. FIG. 16 is a sectional perspective view illustrating a schematic constitution of the thermoelectric conversion device 201D. Further, in the following description, with respect to parts equivalent to those of the thermoelectric conversion device 201C, description will be omitted, and the same reference signs will be given in the drawing.

As illustrated in FIG. 16, like the thermoelectric conversion device 201C, the thermoelectric conversion device 201D of the present embodiment has a constitution in which a substrate 202 on which a plurality of thermoelectric conversion elements 203 are disposed is sandwiched between a first heat transfer plate 204 and a second heat transfer plate 205. Further, the thermoelectric conversion device 201C has a constitution in which the first heat transfer plate 204 and the second heat transfer plate 205 are sealed outside the perimeter of the substrate 202 via a sealing member 206.

In the thermoelectric conversion device 201D of the present embodiment, the plurality of thermoelectric conversion elements 203 and electrodes 207 are alternately provided in a row on a surface of a first surface 202a. In terms of arranged orders of the plurality of thermoelectric conversion elements 203, the arranged order of the first thermoelectric conversion elements 203a, which is formed of an n-type semiconductor, and the second thermoelectric conversion elements 203b, which is formed of an p-type semiconductor, are opposite between the thermoelectric conversion device 201D of the present embodiment and the above-described thermoelectric conversion device 201C. Accordingly, in terms of arranged orders of the plurality of electrodes 207, the arranged order of the four first electrodes 207a, which are configure to be cold junction side electrodes, and the five second electrodes 207b, which are configure to be hot junction side electrode, are opposite between the thermoelectric conversion device 201D of the present embodiment and the above-described thermoelectric conversion device 201C.

For this reason, protrusions 208a by which first heat transfer portions 208 are formed protrude in a region in which they overlap the second electrodes 207b in the top view, and thereby are put in a state in which tips thereof abut on the second electrodes 207b. Thereby, the first heat transfer plate 204 is disposed at an interval S1 from the plurality of thermoelectric conversion elements 203 and first electrodes 207a, and is thermally connected with the thermoelectric conversion elements 203 via the second electrodes 207b and the protrusions 208a (the first heat transfer portions 208), both of which become hot junction sides of the thermoelectric conversion elements 203. Further, the first heat transfer plate 204 is thermally connected with the other end sides of the thermoelectric conversion elements 203 (−X sides of the first thermoelectric conversion elements 203a and +X sides of the second thermoelectric conversion elements 203b) via the protrusions 208a (the first heat transfer portions 208).

On the other hand, protrusions 209a by which second heat transfer portions 209 are formed protrude in a region in which they overlap the second electrodes 207b in the top view, and thereby are put in a state in which tips thereof abut on the second electrodes 207b via the substrate 202. Thereby, the second heat transfer plate 205 is disposed at an interval S2, including the substrate 202, from the plurality of thermoelectric conversion elements 203 and first electrodes 207a, and is thermally connected with the thermoelectric conversion elements 203 via the second electrodes 207b, the protrusions 209a (the second heat transfer portions 209), and the substrate 202, all of which become hot junction sides of the thermoelectric conversion elements 203. Further, the second heat transfer plate 205 is thermally connected with the other end sides of the thermoelectric conversion elements 203 (−X sides of first thermoelectric conversion elements 203a and +X sides of second thermoelectric conversion elements 203b) via the protrusions 209a (the second heat transfer portions 209).

Further, decompressed first spaces K1 are provided between the first heat transfer plate 204, and the plurality of thermoelectric conversion elements 203 and the first electrodes 207a. On the other hand, decompressed second spaces K2 are provided between the second heat transfer plate 205 and a second surface 202b of the substrate 202. The thermoelectric conversion device 201D of the present embodiment can also have a constitution in which the first spaces K1 are filled with a low thermal conductive material (including air) having lower thermal conductivity than the first heat transfer portions 208 and the second spaces K2 are filled with a low thermal conductive material (including air) having lower thermal conductivity than the second heat transfer portions 209.

Furthermore, a pair of through electrodes 210a and 210b are electrically connected to the second electrodes 207b located at opposite ends in an array direction (a first direction) of the thermoelectric conversion elements 203 in a state in which they pass through the protrusions 209a (the second heat transfer portions 209), the second heat transfer plate 205, and the substrate 202 in a thickness direction.

In the thermoelectric conversion device 201D of the present embodiment having the constitution as described above, heat sources (not shown) are disposed on both of the first heat transfer plate 204 and the second heat transfer plate 205. That is, the first heat transfer plate 204 and the second heat transfer plate 205 are disposed on a high temperature (a heat source) side. Thereby, heat conducted from the heat sources to the first heat transfer plate 204 and the second heat transfer plate 205 is conducted to the second electrodes 207b via the first heat transfer portions 208 (the protrusions 208a) and the second heat transfer portions 209 (the protrusions 209a), and thereby the side of the second electrodes 207b of the thermoelectric conversion elements 203 has relatively higher temperature than the side of the first electrodes 207a. A difference in temperature between the first electrodes 207a and the second electrodes 207b of the thermoelectric conversion elements 203 occurs.

In the thermoelectric conversion device 201D of the present embodiment, the first heat transfer plate 204 and the second heat transfer plate 205 are thermally connected with the thermoelectric conversion elements 203 via the aforementioned first heat transfer portions 208 (the protrusions 208a) and the aforementioned second heat transfer portions 209 (the protrusions 209a). Meanwhile, the first heat transfer plate 204 and the second heat transfer plate 205 are disposed at the interval S1 and the interval S2 from the thermoelectric conversion elements 203 and the first electrodes 207a.

In the case of this constitution, the heat conducted from the heat sources to the first heat transfer plate 204 and the second heat transfer plate 205 is concentrically conducted to the second electrodes 207b acting as the hot junctions via the first heat transfer portions 208 (the protrusions 208a) and the aforementioned second heat transfer portions 209 (the protrusions 209a). On the other hand, the heat conducted from the heat sources to the first heat transfer plate 204 and the second heat transfer plate 205 is hardly conducted to the first electrodes 207a acting as the cold junctions. Thereby, a large difference in temperature between the hot junction and the cold junction of each of the thermoelectric conversion elements 203 is obtained, and thereby high output can be obtained.

In the thermoelectric conversion device 201D of the present embodiment, the first heat transfer plate 204 and the second heat transfer plate 205 are sealed outside the perimeter of the substrate 202 on which the aforementioned plurality of thermoelectric conversion elements 203 are provided, and a sealing structure therebetween can be simplified.

Furthermore, in the thermoelectric conversion device 201D of the present embodiment, the decompressed first and second spaces K1 and K2 are provided between the aforementioned first heat transfer plate 204, and the thermoelectric conversion elements 203 and the first electrodes 207a, and within a region within which the second heat transfer plate 205 overlaps the thermoelectric conversion elements 203 of the substrate 202 and the first electrodes 207a in the top view. The first and second spaces K1 and K2 have a function of obstructing (insulating) conduction of the heat. Thereby, higher output can be obtained while enlarging the difference in temperature between the hot junction and the cold junction of each of the thermoelectric conversion elements 203.

In the thermoelectric conversion device 201D of the present embodiment, a pair of terminals 211a and 211b can be electrically connected to the plurality of thermoelectric conversion elements 203 via the pair of through electrodes 210a and 210b that pass through the protrusions 209a (the second heat transfer portions 209), the second heat transfer plate 205, and the substrate 202. Thereby, the sealing structure between the first heat transfer plate 204 and the second heat transfer plate 205 can be simplified without having an influence on a sealing portion between the first heat transfer plate 204 and the second heat transfer plate 205 (a portion where the sealing member 206 is provided).

As described above, in the thermoelectric conversion device 201D of the present embodiment, a thermoelectric conversion characteristic of the thermoelectric conversion device 201D can be improved while simplifying the sealing structure.

### Tenth Embodiment

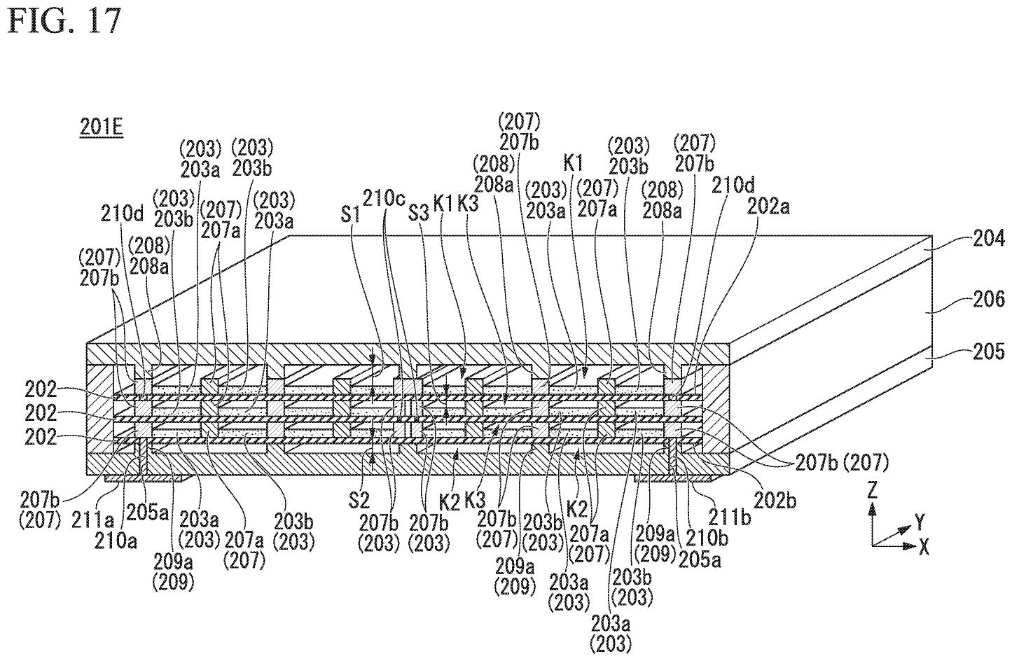

Next, a thermoelectric conversion device 201E illustrated, for example, in FIG. 17 will be described as a tenth embodiment of the present disclosure. FIG. 17 is a sectional perspective view illustrating a schematic constitution of the thermoelectric conversion device 201E. Further, in the following description, with respect to parts equivalent to those of the thermoelectric conversion device 201D, description will be omitted, and the same reference signs will be given in the drawing.

As illustrated in FIG. 17, in addition to the constitution of the thermoelectric conversion device 201D, the thermoelectric conversion device 201E of the present embodiment has a constitution in which a plurality of substrates 202 (three substrates in the present embodiment) on which a plurality of thermoelectric conversion elements 203 are disposed is sandwiched between a first heat transfer plate 204 and a second heat transfer plate 205. Further, the thermoelectric conversion device 201E has a constitution in which the first heat transfer plate 204 and the second heat transfer plate 205 are sealed outside the perimeters of the plurality of substrates 202 via a sealing member 206.

In the thermoelectric conversion device 201E of the present embodiment, first thermoelectric conversion elements 203a provided on each of the substrates 202 and second thermoelectric conversion elements 203b provided on each of the substrates 202 are disposed to alternate with each other in the thickness direction.

Meanwhile, first electrodes 207a provided on each of the substrates 202 and second electrodes 207b provided on each of the substrates 202 are disposed such that the same electrodes overlap one another in a thickness direction. Among them, the second electrodes 207b provided in the middles of the substrates 202 located at second and third layers from the side of the first heat transfer plate 204 are divided into two parts, and are electrically connected to each other via two through electrodes 210c that pass through the substrate 202 of the second layer. Further, the second electrodes 207b provided at opposite ends of the substrates 202 located at first and second layers from the side of the first heat transfer plate 204 are electrically connected via through electrodes 210d that pass through the substrate 202 of the first layer.

Thereby, the thermoelectric conversion device 201E of the present embodiment has a structure in which the first thermoelectric conversion elements 203a provided on each of the substrates 202 and the second thermoelectric conversion elements 203b provided on each of the substrates 202 are alternately connected in series between a pair of terminals 211a and 211b.

Thicknesses of the first electrodes 207a and the second electrodes 207b are thicker than those of the thermoelectric conversion elements 203. Thus, the thermoelectric conversion elements 203 provided on each of the substrates 202 are disposed at an interval S3 including the substrate 202 in thickness directions thereof.

Protrusions 208a by which first heat transfer portions 208 are formed protrude in a region in which they overlap the second electrodes 207b provided on the substrate 202 of the first layer in the top view, and thereby are put in a state in which tips thereof abut on the second electrodes 207b. Thereby, the first heat transfer plate 204 is disposed at an interval S1 from the plurality of thermoelectric conversion elements 203 and the first electrodes 207a provided on the substrate 202 of the first layer. The first heat transfer plate 204 is thermally connected with the thermoelectric conversion elements 203 provided on the substrates 202 via the second electrodes 207b and the protrusions 208a (the first heat transfer portions 208), both of which are provided on the substrates 202, and the substrates 202. Further, the first heat transfer plate 204 is thermally connected with the other end sides of the thermoelectric conversion elements 203 (−X sides of the first thermoelectric conversion elements 203a and +X sides of the second thermoelectric conversion elements 203b) via the protrusions 208a (the first heat transfer portions 208).

On the other hand, protrusions 209a by which second heat transfer portions 209 are formed protrude in a region in which they overlap the second electrodes 207b provided on the substrate 202 of the third layer in the top view, and thereby are put in a state in which tips thereof abut on the second electrodes 207b via the substrate 202. Thereby, the second heat transfer plate 205 is disposed at an interval S2, including the substrate 202 of the third layer, from the plurality of thermoelectric conversion elements 203 and the first electrodes 207a provided on the substrate 202 of the third layer. The second heat transfer plate 205 is thermally connected with the thermoelectric conversion elements 203 provided on the substrates 202 via the second electrodes 207b and the protrusions 209a (the second heat transfer portions 209), both of which are provided on the substrates 202, and the substrates 202. Further, the second heat transfer plate 205 is thermally connected with the other end sides of the thermoelectric conversion elements 203 (the −X sides of the first thermoelectric conversion elements 203a and the +X sides of the second thermoelectric conversion elements 203b) via the protrusions 209a (the second heat transfer portions 209).

Further, decompressed first spaces K1 are provided among the thermoelectric conversion elements 203 and the first electrodes 207a, both of which are provided on the substrate 202 of the first layer, and the first heat transfer plate 204. On the other hand, decompressed second spaces K2 are provided between the second heat transfer plate 205 and a second surface 2b of the substrate 202 of the third layer. Furthermore, third spaces K3 are provided between the substrate 202 of the first layer and the thermoelectric conversion elements 203 provided on the substrate 202 of the second layer and between the substrate 202 of the second layer and the thermoelectric conversion elements 203 provided on the substrate 202 of the third layer. The thermoelectric conversion device 201E of the present embodiment can also have a constitution in which the first spaces K1 are filled with a low thermal conductive material (including air) having lower thermal conductivity than the first heat transfer portions 208, a constitution in which the second spaces K2 are filled with a low thermal conductive material (including air) having lower thermal conductivity than the second heat transfer portions 209, and a constitution in which the third spaces K3 are filled with a low thermal conductive material (including air) having lower thermal conductivity than the first electrodes 207a and the second electrodes 207b.

Like the thermoelectric conversion device 201D, in the thermoelectric conversion device 201E of the present embodiment having the constitution as described above, heat sources (not shown) are disposed on both of the first heat transfer plate 204 and the second heat transfer plate 205. That is, the first heat transfer plate 204 and the second heat transfer plate 205 are disposed on a high temperature (a heat source) side. Thereby, heat conducted from the heat sources to the first heat transfer plate 204 and the second heat transfer plate 205 is conducted to the second electrodes 207b of each of the substrates 202 via the first heat transfer portions 208 (the protrusions 208a) and the second heat transfer portions 209 (the protrusions 209a), and thereby the side of the second electrodes 207b of the thermoelectric conversion elements 203 provided on the substrates 202 has relatively higher temperature than the side of the first electrodes 207a. A difference in temperature between the first electrodes 207a and the second electrodes 207b of the thermoelectric conversion elements 203 provided on the substrates 202 occurs.

In the thermoelectric conversion device 201E of the present embodiment, the first heat transfer plate 204 and the second heat transfer plate 205 are thermally connected with the thermoelectric conversion elements 203 provided on the substrates 202 via the first heat transfer portions 208 (the protrusions 208a) and the second heat transfer portions 209 (the protrusions 209a). Meanwhile, the interval S1 is provided between the first heat transfer plate 204, and the thermoelectric conversion elements 203 and the first electrodes 207a provided on the substrates 202 of the first layer, and the interval S2 is provided between the second heat transfer plate 205 and the thermoelectric conversion elements 203 and the first electrodes 207a provided on the substrates 202 of the third layer. Furthermore, an interval S3 including the substrate 202 is provided between the thermoelectric conversion elements 203 provided on the substrates 202 adjacent to each other in the thickness direction.

In the case of this constitution, the heat conducted from the heat sources to the first heat transfer plate 204 and the second heat transfer plate 205 is concentrically conducted to the second electrodes 207b acting as the hot junctions via the first heat transfer portions 208 (the protrusions 208a) and the aforementioned second heat transfer portions 209 (the protrusions 209a). On the other hand, the heat conducted from the heat sources to the first heat transfer plate 204 and the second heat transfer plate 205 is hardly conducted to the first electrodes 207a acting as the cold junctions. Thereby, a large difference in temperature between the hot junction and the cold junction of each of the thermoelectric conversion elements 203 provided on the substrate 202 is obtained, and thereby high output can be obtained.

In the thermoelectric conversion device 201E of the present embodiment, the first heat transfer plate 204 and the second heat transfer plate 205 are sealed outside the perimeters of the substrates 202 on which the aforementioned plurality of thermoelectric conversion elements 203 are provided, and a sealing structure therebetween can be simplified.

Furthermore, in the thermoelectric conversion device 201E of the present embodiment, the decompressed first spaces K1 are provided between the aforementioned first heat transfer plate 204, and the thermoelectric conversion elements 203 and the first electrodes 207a provided on the substrate 202 of the first layer. Further, the decompressed second spaces K2 are provided between the second heat transfer plate 205 and the regions of the substrate 202 which overlap the thermoelectric conversion elements 203 and the first electrodes 207a provided on the substrate 202 of the third layer in the top view. Further, the third spaces K3 are provided between the substrate 202 of the first layer and the thermoelectric conversion elements 203 provided on the substrate 202 of the second layer and between the substrate 202 of the second layer and the thermoelectric conversion elements 203 provided on the substrate 202 of the third layer.

The first, second and third spaces K1, K2 and K3 have a function of obstructing (insulating) conduction of the heat. Thereby, higher output can be obtained while enlarging the difference in temperature between the hot junction and the cold junction of each of the thermoelectric conversion elements 203.

In the thermoelectric conversion device 201E of the present embodiment, a pair of terminals 211a and 211b can be electrically connected to the plurality of thermoelectric conversion elements 203 provided on the substrates 202 via the pair of through electrodes 210a and 210b that pass through the protrusions 209a (the second heat transfer portions 209), the second heat transfer plate 205, and the substrate 202 of the third layer. Thereby, the sealing structure between the first heat transfer plate 204 and the second heat transfer plate 205 can be simplified without having an influence on a sealing portion between the first heat transfer plate 204 and the second heat transfer plate 205 (a portion where the sealing member 206 is provided).

As described above, in the thermoelectric conversion device 201E of the present embodiment, a thermoelectric conversion characteristic of the thermoelectric conversion device 201E can be improved while simplifying the sealing structure.

The present disclosure is not necessarily limited to the embodiments, and may be modified in various ways without departing from the spirit or teaching of the present disclosure.

For example, the thermoelectric conversion devices 201A to 201E have the constitution in which the pair of through electrodes 210a and 210b and the pair of terminals 211a and 211b are provided close to the aforementioned second heat transfer plate 205, but they can also have a constitution in which the pair of through electrodes 210a and 210b and the pair of terminals 211a and 211b are provided close to the first heat transfer plate 204.

In the thermoelectric conversion devices 201A, 201B and 201C, the case where the first heat transfer plate 204 is disposed on the high temperature (the heat source) side and the second heat transfer plate 205 is disposed on the low temperature (heat radiation/cooling) side is given by way of example. However, the second heat transfer plate 205 may be disposed on the high temperature (the heat source) side, and the first heat transfer plate 204 may be disposed on the low temperature (heat radiation/cooling) side. Thereby, the heat from the heat source may be conducted from the side of the second heat transfer plate 205. In this case, the first electrodes 207a become the hot junction side electrodes, and the second electrodes 207b become the cold junction side electrodes.

While preferred embodiments of the disclosure have been described and illustrated above, it should be understood that these are exemplary of the disclosure and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A thermoelectric conversion device comprising:
a substrate having a first surface and a second surface that face each other in a thickness direction;
at least one thermoelectric conversion element which is provided in a surface on a side of at least one of the first surface and the second surface;
a heat transfer member disposed on the side of the substrate, on which the at least one thermoelectric conversion element is provided, with an interval from at least a part of the at least one thermoelectric conversion element; and
at least one heat transfer portion configured to thermally connect the at least one thermoelectric conversion element and the heat transfer member,
wherein an interspace between the substrate and the heat transfer member is sealed outside a perimeter of the at least one thermoelectric conversion element.

2. The thermoelectric conversion device according to claim 1, wherein a space is formed between the substrate and the heat transfer member.

3. The thermoelectric conversion device according to claim 2, wherein the space is decompressed.

4. The thermoelectric conversion device according to claim 1, further comprising at least one through electrode configured to pass through at least one of the substrate and the heat transfer member in the thickness direction,
wherein the at least one thermoelectric conversion element is electrically connected to the at least one through electrode.

5. The thermoelectric conversion device according to claim 2, further comprising at least one through electrode configured to pass through at least one of the substrate and the heat transfer member in the thickness direction,
wherein the at least one thermoelectric conversion element is electrically connected to the at least one through electrode.

6. The thermoelectric conversion device according to claim 3, further comprising at least one through electrode configured to pass through at least one of the substrate and the heat transfer member in the thickness direction,
wherein the at least one thermoelectric conversion element is electrically connected to the at least one through electrode.

7. The thermoelectric conversion device according to claim 1, wherein the at least one heat transfer portion is thermally connected with one end side or other end side of the at least one thermoelectric conversion element.

8. The thermoelectric conversion device according to claim 7, further comprising:
at least one first electrode provided on the one end side of the at least one thermoelectric conversion element; and
at least one second electrode provided on the other end side of the at least one thermoelectric conversion element,
wherein the heat transfer member is thermally connected with the one end side or the other end side of the at least one thermoelectric conversion element via the at least one heat transfer portion that abuts on the at least one first electrode or the at least one second electrode.

9. The thermoelectric conversion device according to claim 8, wherein:
the at least one thermoelectric conversion element comprises a plurality of thermoelectric conversion elements provided in a row in the surface on the side of at least one of the first surface and the second surface of the substrate;
the at least one first electrode comprises a plurality of first electrodes and the at least one second electrode comprises a plurality of second electrodes; and
the first electrodes and the second electrodes are provided in a row in a direction of the row of the thermoelectric conversion elements.

10. The thermoelectric conversion device according to claim 1, wherein the at least one heat transfer portion is thermally connected with a central part of the at least one thermoelectric conversion element.

11. The thermoelectric conversion device according to claim 10, wherein the heat transfer member has a structure in which at least a first heat transfer layer and a second heat transfer layer having higher thermal conductivity than the first heat transfer layer are stacked, and a part of the second heat transfer layer form the at least one heat transfer portion.

12. The thermoelectric conversion device according to claim 10, wherein:
the at least one thermoelectric conversion element comprises a plurality of thermoelectric conversion elements provided in a row in the surface on the side of at least one of the first surface and the second surface of the substrate; and
the heat transfer member constitutes a part of an electrode electrically connected to each of the thermoelectric conversion elements.

13. A thermoelectric conversion device comprising:
at least one thermoelectric conversion element which is provided on a specific plane;
a first heat transfer member disposed on one side of the specific plane with an interval from at least a part of the at least one thermoelectric conversion element, interposing the at least one thermoelectric conversion element between the one side of the specific plane and other side of the specific plane;
a first heat transfer portion configured to thermally connect the at least one thermoelectric conversion element and the first heat transfer member;
a second heat transfer member disposed on the other side of the specific plane with an interval from at least a part of the at least one thermoelectric conversion element, interposing the at least one thermoelectric conversion element between the one side of the specific plane and the other side of the specific plane; and
a second heat transfer portion configured to thermally connect the at least one thermoelectric conversion element and the second heat transfer member,
wherein an interspace between the first heat transfer member and the second heat transfer member is sealed outside a perimeter of the at least one thermoelectric conversion element.

14. The thermoelectric conversion device according to claim 13, wherein a space is formed between the first heat transfer member and the second heat transfer member.

15. The thermoelectric conversion device according to claim 14, wherein the space is decompressed.

16. The thermoelectric conversion device according to claim 13, further comprising at least one through electrode configured to pass through at least one of the first heat transfer member and the second heat transfer member in a thickness direction,
wherein the at least one thermoelectric conversion element is electrically connected to the at least one through electrode.

17. The thermoelectric conversion device according to claim 13, wherein:
the first heat transfer portion is thermally connected with one end side or the other end side of the at least one thermoelectric conversion element; and
the second heat transfer portion is thermally connected with the one end side or the other end side of the at least one thermoelectric conversion element.

18. The thermoelectric conversion device according to claim 17, further comprising:
at least one first electrode provided on the one end side of the at least one thermoelectric conversion element; and
at least one second electrode provided on the other end side of the at least one thermoelectric conversion element
wherein the first heat transfer member is thermally connected with the one end side or the other end side of the at least one thermoelectric conversion element via the first heat transfer portion that abuts on the at least one first electrode or the at least one second electrode, and
the second heat transfer member is thermally connected with the one end side or the other end side of the at least one thermoelectric conversion element via the second heat transfer portion that abuts on the at least first electrode or the at least one second electrode.

19. The thermoelectric conversion device according to claim 18, wherein:
the at least one thermoelectric conversion element comprises a plurality of thermoelectric conversion elements that are provided in a row on the specific plane;
the at least first electrode comprises a plurality of first electrodes and the at least second electrode comprises a plurality of second electrodes; and
the first electrodes and the second electrodes are provided in a row in a direction of the row of the thermoelectric conversion elements.

20. The thermoelectric conversion device according to claim 13, further comprising a substrate having a first surface and a second surface that face each other in a thickness direction,
wherein the at least one thermoelectric conversion element is provided in a surface on a side of at least one of the first surface and the second surface.
